(19) United States
(12) Patent Application Publication
(10) Pub. No.: US 2025/0141363 A1
(43) Pub. Date: May 1, 2025

(54) RECTIFIER MODULE AND TRANSFORMER

(71) Applicant: Delta Electronics (Shanghai) CO., LTD., Shanghai (CN)

(72) Inventors: Yuesen GUO, Shanghai (CN); Shiwei LIU, Shanghai (CN); Jun ZHANG, Shanghai (CN); Kai DONG, Shanghai (CN); Haijun YANG, Shanghai (CN); Jinfa ZHANG, Shanghai (CN); Chang XU, Shanghai (CN)

(73) Assignee: Delta Electronics (Shanghai) CO., LTD., Shanghai (CN)

(21) Appl. No.: 18/920,952

(22) Filed: Oct. 20, 2024

(30) Foreign Application Priority Data
Oct. 27, 2023 (CN) 2023114128442
Oct. 27, 2023 (CN) 2023229073005
Mar. 15, 2024 (CN) 202420513644X
Mar. 15, 2024 (CN) 2024103028553
Jun. 3, 2024 (CN) 202410713018X
Jun. 3, 2024 (CN) 2024212573588

(51) Int. Cl. H02M 7/00; H01F 27/24; H01F 27/28; H05K 1/18

(52) U.S. Cl. CPC H02M 7/003; H01F 27/24; H01F 27/28; H05K 1/181

(57) ABSTRACT

The present disclosure provides a rectifier module and a transformer, the rectifier module includes a transformer and a rectifier board, the transformer includes: a magnetic core; a first winding; and a second winding, the magnetic core includes a magnetic column, the first winding is arranged on the magnetic column, and the second winding is arranged outside the first winding; comb-type pins are respectively arranged on opposite sides of the second winding, the comb-type pins are arranged along a first direction, and the comb-type pins include comb teeth and comb gaps; the rectifier board includes: a circuit board; and a plurality of switch element groups arranged along the first direction, the switch element group includes at least one switch element; along the second direction, the comb teeth are adjacent to the switch element; the first direction and the second direction are perpendicular to each other.

### CROSS REFERENCE

The present application is based upon and claims priority to Chinese Application No. 2023114128442, filed on Oct. 27, 2023, Chinese Application No. 2023229073005, filed on Oct. 27, 2023, Chinese Application No. 2024103028553, filed on Mar. 15, 2024, Chinese Application No. 202420513644X, filed on Mar. 15, 2024, Chinese Application No. 202410713018X, filed on Jun. 3, 2024, and Chinese Application No. 2024212573588, filed on Jun. 3, 2024, and the entire contents thereof are incorporated herein by reference.

### TECHNICAL FIELD

The present disclosure relates to the field of power electronics technology, and in particular to a rectifier module and a transformer.

### BACKGROUND

As people's requirements for smart life increase, the demand for data processing is growing in the world. The global energy consumption for data processing reaches hundreds of billions or even trillions of degrees per year on average; and a large data center can occupy tens of thousands of square meters. Therefore, high efficiency and high power density are key indicators for the healthy development of this industry.

As the integration of electrical devices per unit volume continues to increase, the electricity that powers these electrical devices is expected to have higher efficiency, higher power density and smaller volume to support the overall power demand. In order to meet the demand for high power density, the demand for low-voltage, high-current power supplies is increasing. With the development of low-voltage, high-current power supplies, the processing of high-current windings has become increasingly important. The form of the winding must not only cooperate with the placement of the secondary rectifier transistors, but also have high manufacturability.

### SUMMARY

The embodiments of the present disclosure provide a rectifier module and a transformer.

According to a first aspect of an embodiment of the present disclosure, a rectifier module is provided, including a including a transformer and a rectifier board, wherein the transformer includes: a magnetic core, including a magnetic column; a first winding, arranged on the magnetic column; and a second winding, arranged outside the first winding; wherein, two opposite sides of the second winding are respectively provided with comb-type pins, the comb-type pins are arranged along a first direction, the comb-type pins include at least two comb teeth, and a comb gap is provided adjacent to the comb teeth; and wherein the rectifier board includes: a circuit board; and a plurality of switch element groups arranged along the first direction, configured for rectifying an output current of the second winding, the switch element group being disposed on the circuit board and including at least one switch element; wherein in a second direction, the comb teeth are adjacent to the switch element; and the first direction and the second direction are perpendicular to each other.

According to a second aspect of an embodiment of the present disclosure, a rectifier module is provided, including a transformer and a rectifier board, wherein the transformer includes: a magnetic core, including a magnetic column; a first winding, disposed on the magnetic column; and a second winding, arranged outside the first winding; wherein, the second winding includes a first pin and a second pin which are arranged opposite to each other; wherein the rectifier board includes: a circuit board; and a plurality of switch element groups arranged along a first direction, used for rectifying an output current of the second winding, the switch element group being disposed on the circuit board and including at least one switch element; wherein the first pin and the second pin are bar-type pins, and are arranged on the circuit board in a surface mounting manner, along a second direction, the first pin and the second pin are adjacent to the switch element; and the first direction and the second direction are perpendicular to each other.

According to a third aspect of an embodiment of the present disclosure, a transformer is provided, including a magnetic core, a first winding and a second winding; the magnetic core includes a magnetic column, the first winding is arranged on the magnetic column, and the second winding is arranged outside the first winding; wherein two opposite sides of the second winding are respectively provided with comb-type pins, the comb-type pins are arranged along a first direction, the comb-type pins include at least two comb teeth, and a comb gap is arranged adjacent to the comb teeth.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for ordinary technicians in this field, other accompanying drawings can be obtained based on these accompanying drawings without creative work.

FIG. 1A is a schematic diagram of the structure of a rectifier module according to a first embodiment of the present disclosure.

FIG. 1B is a first structural diagram of a transformer according to a first embodiment of the present disclosure.

FIG. 1C is a second structural schematic diagram of the transformer of the first embodiment of the present disclosure.

FIG. 1D is a first structural schematic diagram of a rectifier board according to a first embodiment of the present disclosure.

FIG. 1D′ is a second structural schematic diagram of the rectifier board according to a first embodiment of the present disclosure.

FIG. 1D″ is a third structural schematic diagram of the rectifier board according to a first embodiment of the present disclosure.

FIG. 1E is a third schematic diagram of the structure of the transformer according to a first embodiment of the present disclosure.

FIG. 1F is an assembly diagram of the rectifier module according to a first embodiment of the present disclosure.

FIG. 1G is a schematic diagram of the structure of the rectifier module mounted with output terminals according to a first embodiment of the present disclosure.

FIG. 1G′ is a schematic structural diagram of a partial cross-section of the rectifier module shown in FIG. 1G with the conductive sheet exposed.

FIG. 1H is a schematic diagram of the structure of the second winding according to a first embodiment of the present disclosure.

FIG. 1I is a fourth structural schematic diagram of the transformer according to a first embodiment of the present disclosure.

FIG. 2A is a schematic diagram of the structure of a rectifier module according to a second embodiment of the present disclosure.

FIG. 2B is a schematic diagram of the structure of the transformer according to a second embodiment of the present disclosure.

FIG. 2C is a schematic diagram of the structure of the rectifier board according to a second embodiment of the present disclosure.

FIG. 3A is a schematic diagram of the structure of a rectifier module according to a third embodiment of the present disclosure.

FIG. 3B is a schematic diagram of the structure of the transformer according to a third embodiment of the present disclosure.

FIG. 3C is a first structural diagram of a rectifier board according to a third embodiment of the present disclosure.

FIG. 3C′ is a schematic structural diagram of the other side of the rectifier board shown in FIG. 3C.

FIG. 3D is a second structural schematic diagram of the rectifier board according to a third embodiment of the present disclosure.

FIG. 3D′ is a schematic structural diagram of the other side of the rectifier board shown in FIG. 3D.

FIG. 3E is a third structural schematic diagram of the rectifier board according to a third embodiment of the present disclosure.

FIG. 3F is a schematic diagram of the assembly of the rectifier module according to a third embodiment of the present disclosure.

FIG. 3G is a schematic diagram of the structure of the rectifier module mounted with output terminals according to a third embodiment of the present disclosure.

FIG. 4A is a schematic diagram of the structure of a rectifier module according to a fourth embodiment of the present disclosure.

FIG. 4B is a schematic diagram of the structure of the transformer according to a fourth embodiment of the present disclosure.

FIG. 4C is a schematic diagram of the structure of the rectifier board according to a fourth embodiment of the present disclosure.

FIG. 4D is a schematic diagram of the second winding according to a fourth embodiment of the present disclosure being unfolded.

FIG. 5A is a schematic diagram of the structure of a rectifier module according to a fifth embodiment of the present disclosure.

FIG. 5B is a schematic diagram of the structure of the transformer according to a fifth embodiment of the present disclosure.

FIG. 5C is an assembly diagram of the rectifier module according to a fifth embodiment of the present disclosure.

FIG. 6A is a schematic diagram of the structure of a rectifier module according to a sixth embodiment of the present disclosure.

FIG. 6B is a schematic diagram of the structure of the transformer according to a sixth embodiment of the present disclosure.

FIG. 6C is an assembly diagram of the rectifier module according to a sixth embodiment of the present disclosure.

FIG. 7A is a first structural diagram of a rectifier module according to a seventh embodiment of the present disclosure.

FIG. 7B is a second structural diagram of the rectifier module according to a seventh embodiment of the present disclosure.

FIG. 8 is a schematic structural diagram of a rectifier module according to an eighth embodiment of the present disclosure.

FIG. 9A is a schematic structural diagram of a rectifier module according to a ninth embodiment of the present disclosure.

FIG. 9B is a schematic diagram of the structure of the second winding according to a ninth embodiment of the present disclosure.

FIG. 10A is a first structural diagram of a rectifier module according to a tenth embodiment of the present disclosure.

FIG. 10B is a second structural diagram of the rectifier module according to a tenth embodiment of the present disclosure.

FIG. 10C is a third structural diagram of the rectifier module according to a tenth embodiment of the present disclosure.

FIG. 11 is a schematic diagram of the structure of a transformer according to an eleventh embodiment of the present disclosure.

### DETAILED DESCRIPTION

Example embodiments will now be described more fully with reference to the accompanying drawings. However, example embodiments can be implemented in many forms and should not be construed as limited to the embodiments set forth herein; rather, these embodiments are provided so that this disclosure will be comprehensive and complete and will fully convey the concepts of the example embodiments to those skilled in the art. The same reference numerals in the figures represent the same or similar parts, and thus their repeated description will be omitted.

The described features, structures, or characteristics of the present disclosure may be combined in one or more embodiments in any suitable manner. In the following description, many specific details are provided to provide a full understanding of the embodiments of the present disclosure. However, those skilled in the art will appreciate that the technical solutions of the present disclosure may be practiced while omitting one or more of the specific details, or other methods, components, devices, steps, etc. may be adopted. In other cases, known methods, devices, implementations or operations are not shown or described in detail to avoid blurring the various aspects of the present disclosure.

The accompanying drawings are only schematic diagrams of the present disclosure, and the same reference numerals in the drawings represent the same or similar parts, so their repeated description will be omitted. Some block diagrams shown in the accompanying drawings do not necessarily correspond to physically or logically independent entities. These functional entities can be implemented in software form, or implemented in at least one hardware module or integrated circuit, or implemented in different networks and/or processor devices and/or microcontroller devices.

In this specification, the terms “a”, “an”, “the”, “said” and “at least one” are used to indicate the presence of at least one element/component/etc.; the terms “comprising”, “including” and “having” are used to indicate an open-ended inclusion and mean that in addition to the listed elements/components/etc., there may be other elements/components/etc.; the terms “first”, “second” and “third” etc. are only used as labels and are not intended to limit the quantity of their objects; the terms “and B are arranged along a first direction”, “A and B are arranged along a second direction”, etc. do not mean that A and B must be arranged in a straight line, and A and B may have a certain deviation or misalignment along the first direction.

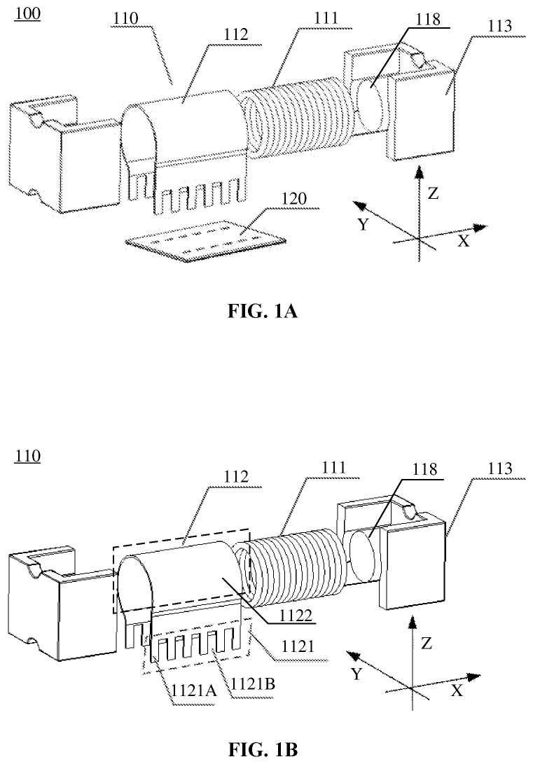

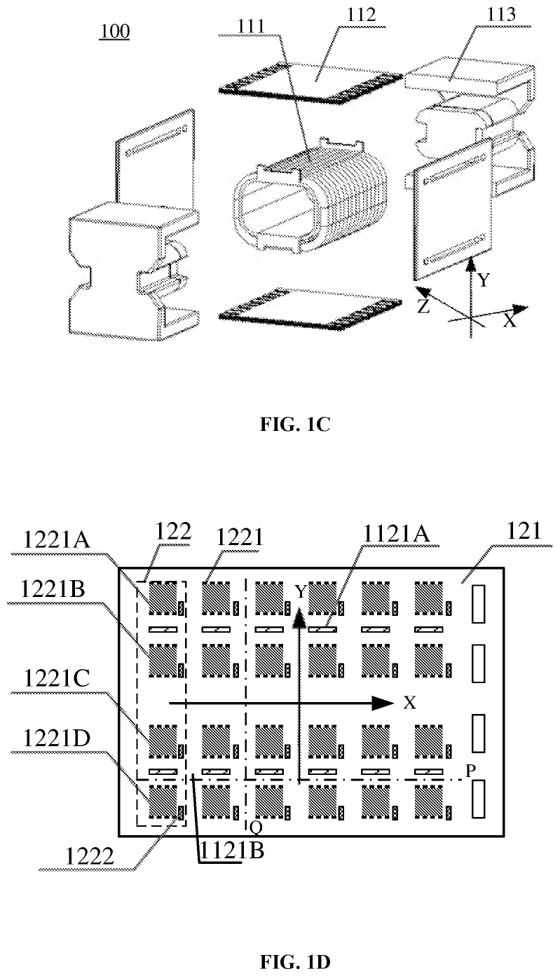

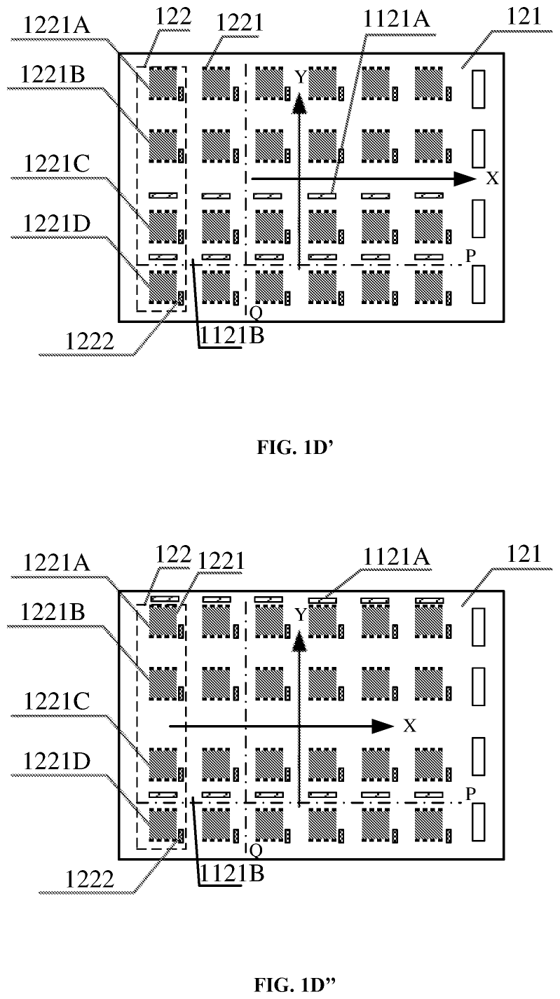

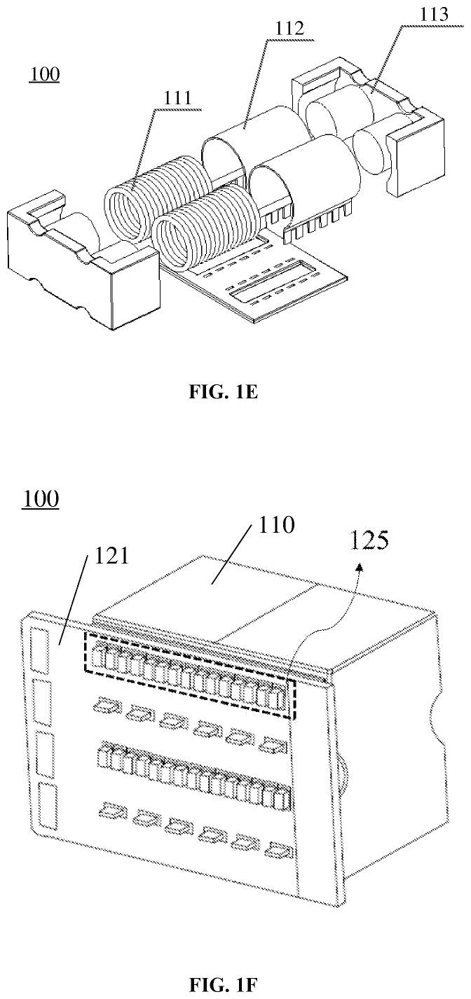

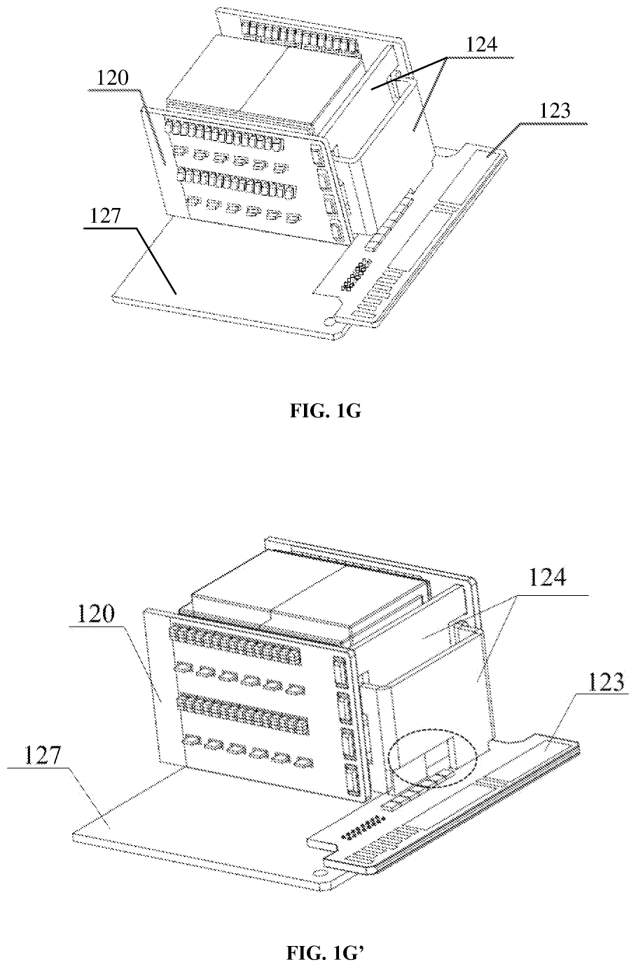

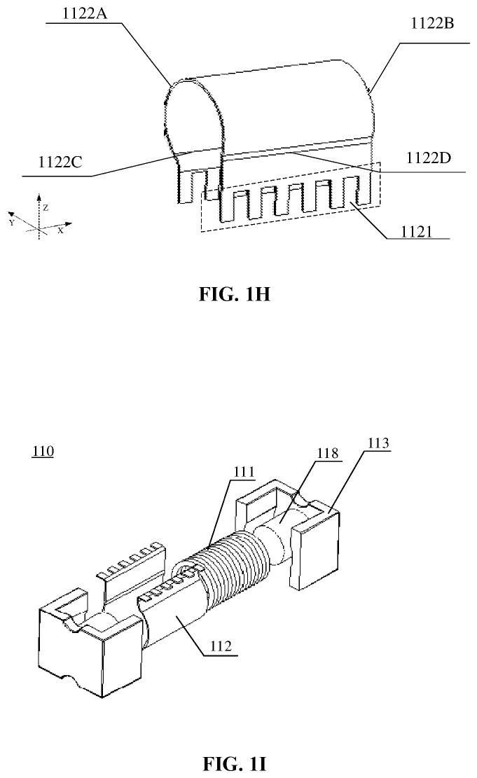

Reference is made to FIGS. 1A, 1B, 1C, 1D, 1D′, 1D″, 1E, 1F, 1G, 1G′, 1H, and 1I. FIG. 1A is a schematic diagram of the structure of the rectifier module of the first embodiment of the present disclosure, FIG. 1B is a schematic diagram of the structure of the transformer of the first embodiment of the present disclosure, FIG. 1C is a schematic diagram of the structure of the transformer of the first embodiment of the present disclosure, and FIG. 1D is a schematic diagram of the structure of the rectifier board of the first embodiment of the present disclosure. FIG. 1D′ is a schematic diagram of the structure of the rectifier board of the first embodiment of the present disclosure. FIG. 1D″ is a schematic diagram of the structure of the rectifier board of the first embodiment of the present disclosure. FIG. 1E is a schematic diagram of the structure of the transformer of the first embodiment of the present disclosure. FIG. 1F is an assembly diagram of the rectifier module of the first embodiment of the present disclosure. FIG. 1G is a schematic diagram of the structure of the rectifier module of the first embodiment of the present disclosure mounted with output terminals. FIG. 1G′ is a schematic diagram of the structure of the rectifier module shown in FIG. 1G with a partial cross-section showing the conductive sheet. FIG. 1H is a schematic diagram of the structure of the second winding of the first embodiment of the present disclosure. FIG. 1I is a schematic diagram of the structure of the transformer of the first embodiment of the present disclosure.

As shown in FIG. 1A, the rectifier module 100 includes: a transformer 110 and a rectifier board 120. The transformer 110 includes: a magnetic core 113, a first winding 111 and a second winding 112. The transformer 110 changes the AC voltage through the first winding 111 and the second winding 112. The rectifier board 120 is a circuit board including a plurality of switch element groups (not shown in FIG. 1A). The rectifier board 120 is electrically connected to the transformer 110 and is used to rectify the AC power of the transformer 110 into DC power. It should be noted that, for the sake of simplicity, the switch elements on the rectifier board 120 are not shown in the figure, and the rectifier board 120 here is only used for illustration. In addition, in other embodiments of the present disclosure, a substrate (not shown in the figure) may be further provided between the transformer 110 and the rectifier board 120, and a through hole is provided on the substrate for the comb-type pins of the second winding 112 to pass through, so as to fix the second winding 112.

As shown in FIG. 1B, the transformer 110 includes: a magnetic core 113, a first winding 111 and a second winding 112. The first winding 111 is formed of a coil and is used to receive the input alternating current. The magnetic core 113 includes a magnetic column 118, and the coil forming the first winding 111 is arranged on the magnetic column 118. The magnetic core 113 is mainly used for magnetic conduction. The second winding 112 is arranged outside the first winding 111 and is used to electrically connect to the rectifier board 120, and input the alternating current output by the transformer 110 into the rectifier board 120 for rectification. Comb-type pins 1121 are respectively arranged on opposite sides of the second winding 112. The comb-type pins 1121 are arranged along the first direction X. The comb-type pin 1121 includes at least two comb teeth 1121A, and a comb gap 1121B is arranged adjacent to the comb teeth 1121A. The comb-type pin 1121 is arranged alternately by a plurality of comb teeth 1121A and comb gaps 1121B, presenting a comb-type structure. The transformer 110 is electrically connected to the rectifier board 120 through the comb teeth 1121A. It should be noted that the shape of the comb-type pin 1121 shown in the figure is only an example. In other embodiments, the shape of the comb-type pin 1121 is not limited, and as long as it can be electrically connected, it should be considered to belong to the protection scope of this application. In some embodiments of the present disclosure application the magnetic column 118 is a cylinder, and the axial direction of the magnetic column 118 is the first direction X.

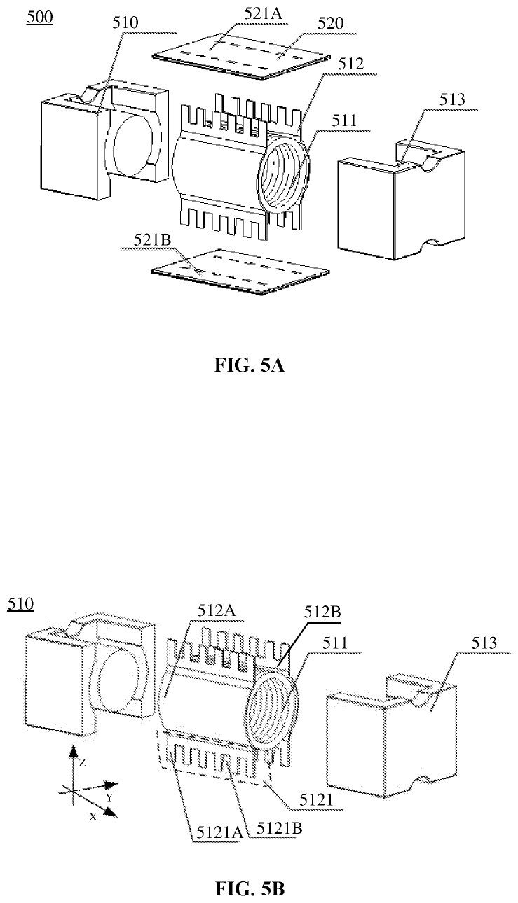

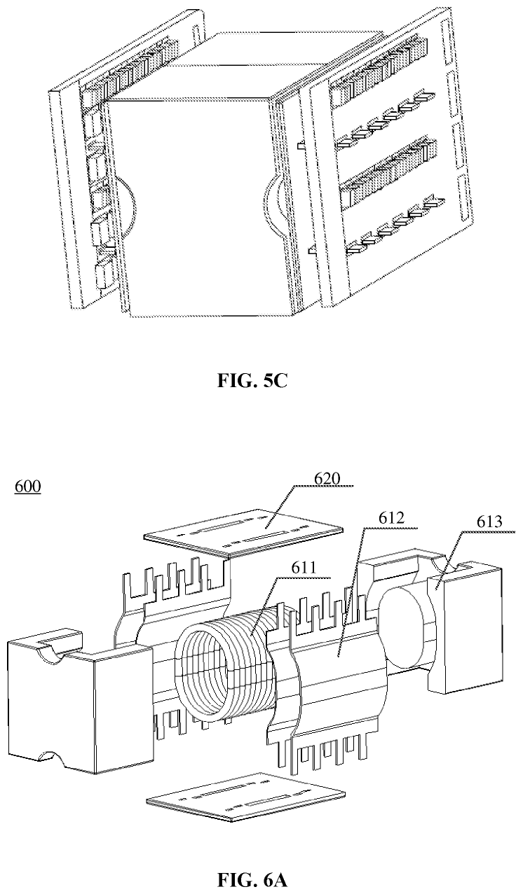

The so-called opposite sides of the second winding 112 refer to the two ends of the second winding 112, and the specific position thereof is related to the shape and structure of the second winding 112. For example, the opposite sides of the second winding 112 shown in FIG. 1B are the opposite sides along the second direction Y, and the opposite sides of the second winding 512 shown in FIG. 5A are the opposite sides along the third direction Z.

Please refer to FIG. 1B again, in which the second winding 112 is U-shaped, and comb-type pins are arranged at two free ends of the U-shaped second winding 112. In other embodiments of the present disclosure, the second winding 112 may also be in other shapes.

In an exemplary embodiment, the second winding 112 may be a metal sheet or a PCB winding. Specifically, the metal sheet includes an iron sheet, a copper sheet, an aluminum sheet, a nickel sheet, a tungsten sheet, a molybdenum sheet, a cobalt sheet, etc., and also includes metal sheets made of various metal alloys, including stainless steel sheets, nickel-based alloy sheets, copper alloy sheets, and aluminum alloy sheets, etc. The PCB winding may be a flexible PCB winding or a rigid PCB winding. For example, in the embodiment shown in FIG. 1B, the second winding 112 may also be a flexible PCB winding, thereby bending into a U-shaped winding. In the embodiment shown in FIG. 1C, the second winding 112 may also be a rigid PCB winding. In the embodiment shown in FIG. 1C, except that the second winding 112 is made of different materials, the other parts are no different from the structure of the aforementioned embodiment, and will not be repeated here.

In an exemplary embodiment, as shown in FIG. 1B, the comb-type pin 1121 and the rectifier board 120 can be welded through via holes. In other embodiments of the present disclosure, as shown in FIG. 1I, the comb-type pin 1121 and the rectifier board 120 can also be welded through a surface mounting method.

It should be noted that the first direction X, the second direction Y, and the third direction Z referred to in the present disclosure are all set based on the circuit board. When the position of the circuit board changes, the first direction X, the second direction Y, and the third direction Z may be different according to different embodiments, as shown in FIGS. 1A and 1C.

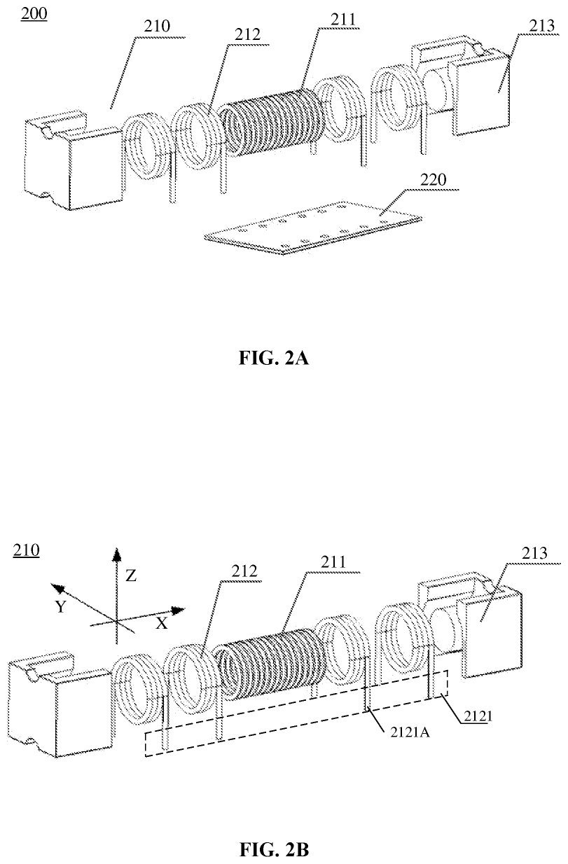

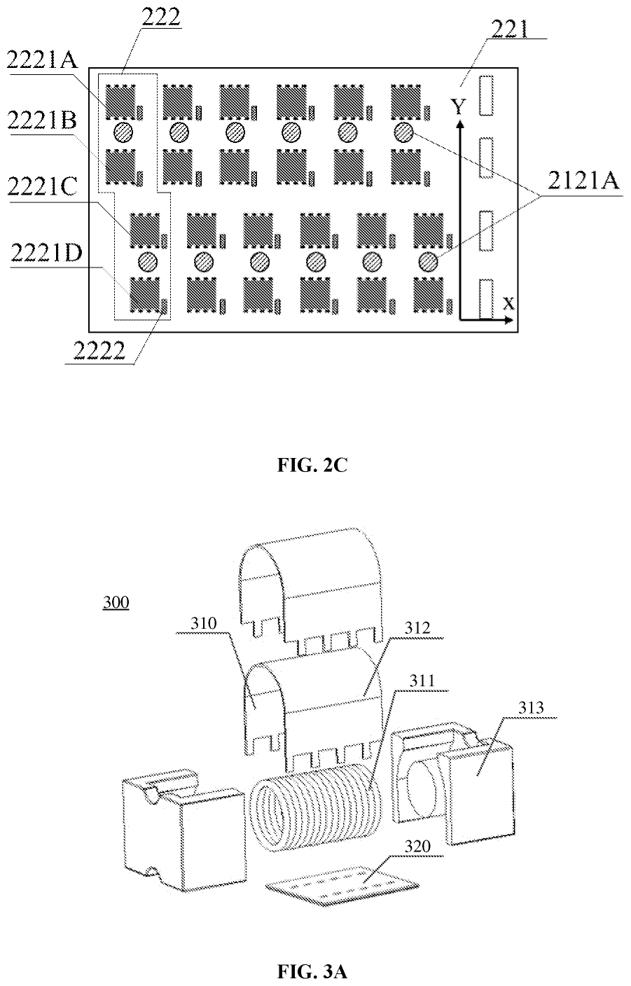

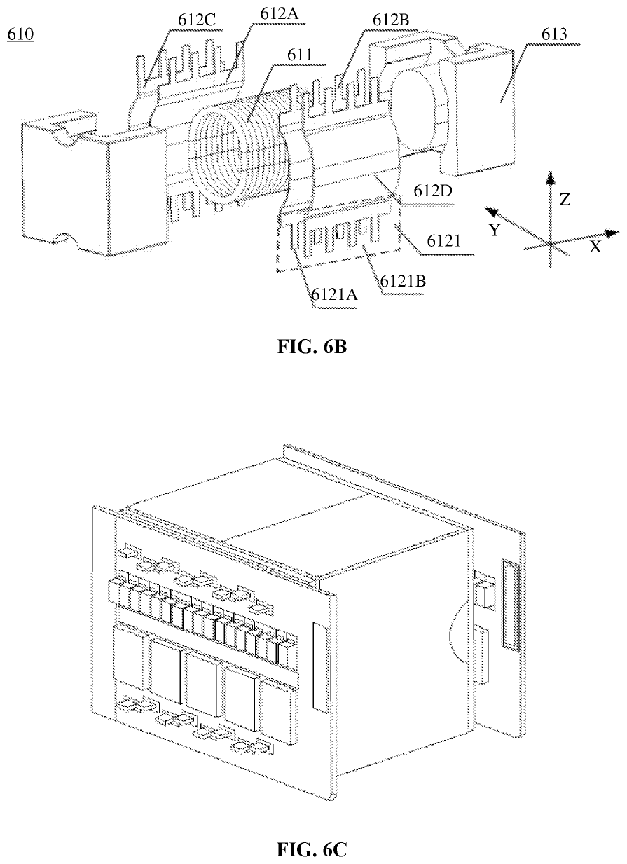

In some embodiments of the present disclosure, as shown in FIG. 1B and FIG. 1H, the magnetic column 118 extends along the first direction X, and the second winding 112 includes a main body 1122 (for example, as shown in the dotted box in FIG. 1B) and a comb-type pin 1121 (as shown in the dotted box in FIG. 1B and FIG. 1H), and the main body 1122 includes a first end 1122A and a second end 1122B that are oppositely arranged along the first direction X, and a third end 1122C and a fourth end 1122D that are oppositely arranged, wherein the comb-type pin 1121 is connected to the third end 1122C and the fourth end 1122D, and the main body 1122 extends along the first direction. That is, the extension direction of the main body 1122 of the second winding 112 is the same as the extension direction of the magnetic column 118. In an exemplary embodiment, the second winding 112 is integrally formed, and in other embodiments of the present disclosure, the second winding 112 may include a plurality of sub-windings. Each sub-winding may include a comb-type pin, and each sub-winding may also be integrally formed. At the same time, the sub-windings may be arranged in various ways. For example, the second windings shown in FIGS. 5A and 6A are formed of a plurality of half-turn windings. In other embodiments of the present disclosure, it is possible that not each of the plurality of sub-windings forming the second winding has a comb-type pin. For example, the second windings shown in FIGS. 2A and 2B are formed of a plurality of coils, and the pins on both sides of the coil group formed of the plurality of coils are comb-type pins.

In an exemplary embodiment, as shown in FIG. 1E, the magnetic core 113 includes at least two magnetic columns. Exemplarily, the at least two magnetic columns of the magnetic core 113 are arranged along the second direction Y The first winding 111 and the second winding 112 are provided on the at least two magnetic columns. It should be noted that the magnetic columns referred to herein indicate magnetic columns provided with windings. In the embodiments shown in FIG. 1A, 1B, etc., in addition to magnetic columns provided with windings, magnetic columns not provided with windings may also exist. This case does not limit whether magnetic columns not provided with windings are provided, and the number and position of magnetic columns not provided with windings.

In an exemplary embodiment, as shown in FIG. 1D, the rectifier board 120 includes: a circuit board 121 and a plurality of switch element groups 122, wherein the switch element group 122 is shown in the dotted box in FIG. 1D. The plurality of switch element groups 122 are disposed on the circuit board 121. The plurality of switch element groups 122 are arranged along the first direction X, and are used to rectify the output current of the second winding 112. Each switch element group 122 includes at least one switch element 1221.

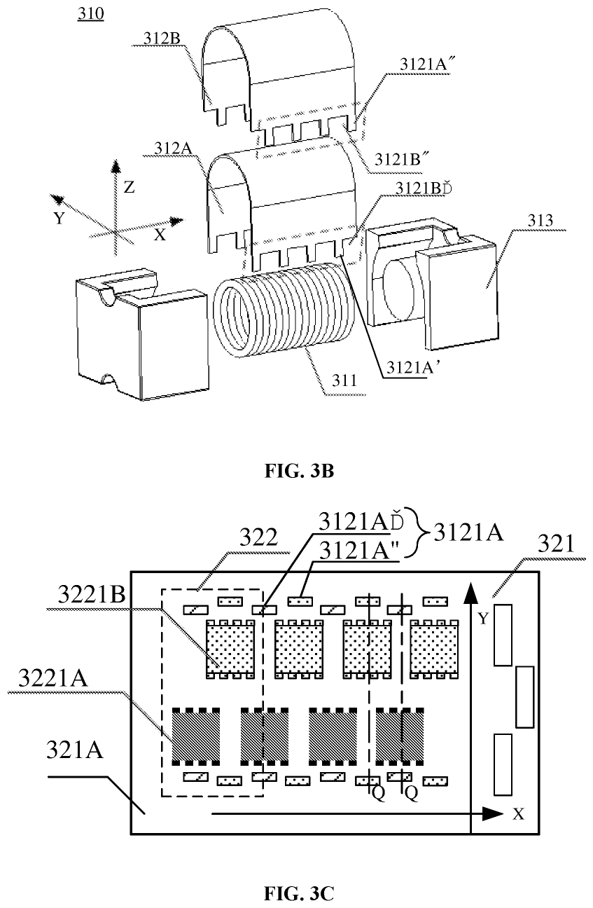

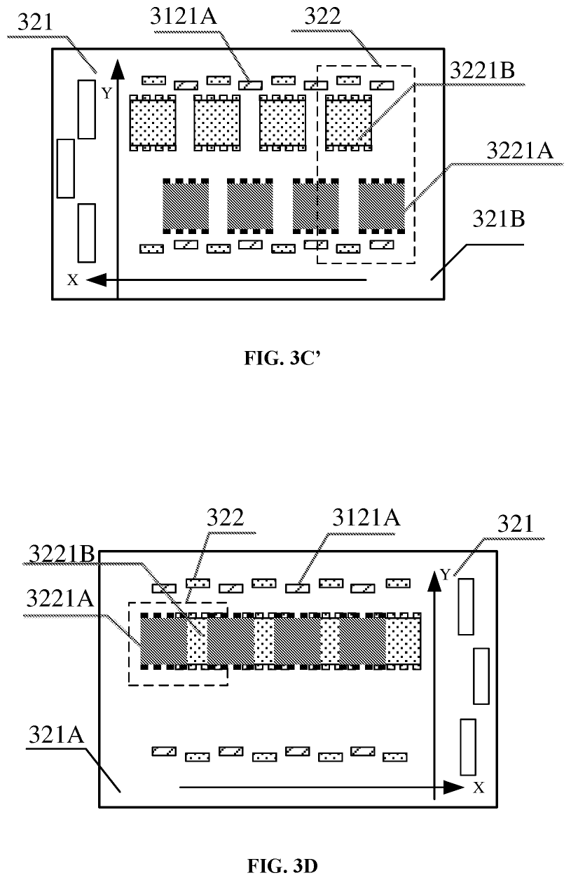

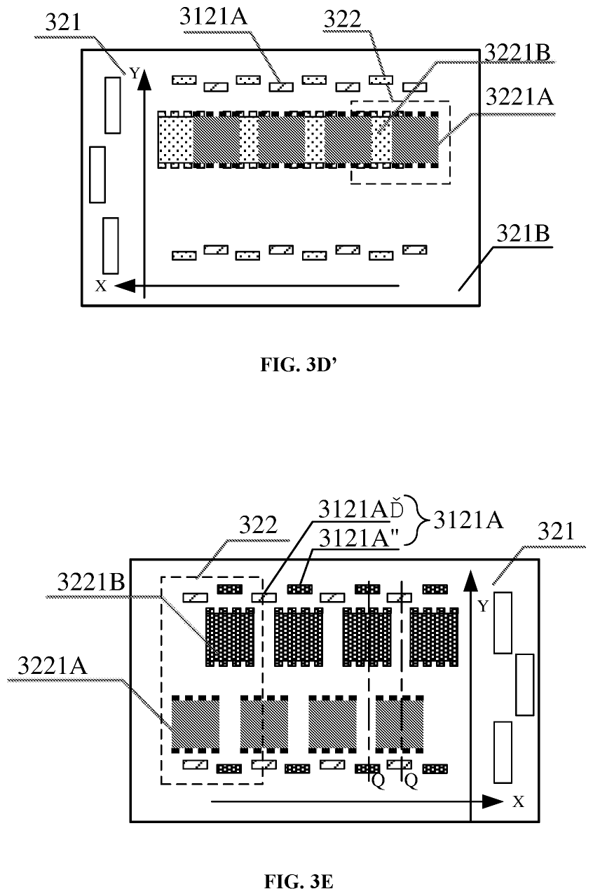

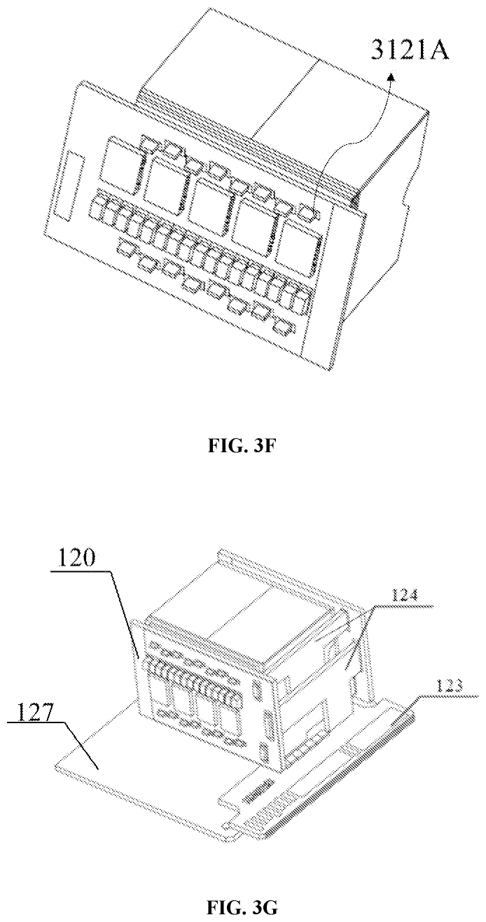

In the embodiment, the switch elements 1221 in the same switch element group 122 are arranged along the second direction Y Also, along the second direction Y, the comb teeth 1121A are arranged adjacent to the switch element 1221. On the circuit board 121, a first wire P is arranged along the first direction X, and a second wire Q is arranged along the second direction Y. At least part of the second wire Q is formed between the comb spaces 1121B arranged opposite to each other in the second winding 112. The first wire P and the second wire Q are electrically connected to part of the switch elements 1221, respectively, wherein the potential at the connection point between the first wire P or the second wire Q and the switch element is the same, and part of the switch elements 1221 are connected to form a rectifier circuit. The first direction X and the second direction Y are perpendicular to each other. It should be noted that the so-called “a and b are arranged along the first direction”, “a and b are arranged along the second direction”, etc. do not mean that a and b must be arranged in a straight line. Due to the needs of the process or actual manufacturing, when a and b are arranged along a certain direction, the two may have a certain deviation or misalignment in the same direction. As shown in FIG. 3F, the comb teeth 3121A arranged along the first direction on the circuit board are not arranged in a straight line between adjacent comb teeth 3121A, and there is a certain misalignment between them. Similarly, “a and b are arranged along the first direction”, “a and b are arranged along the second direction” can also mean that a and b overlap or do not overlap in a certain direction, such as the case of non-overlapping as shown in FIG. 1D, and the case of overlapping as shown in FIGS. 3D and 3D′.

In some embodiments of the present disclosure, along the second direction Y, the comb teeth 1121A of the comb-type pins 1121 on both sides of the second winding 112 are adjacent to the switch element group 122, and at least one switch element is included between the comb teeth 1121A of the comb-type pins 1121 on both sides of the second winding 112, as shown in FIGS. 1D, 1D′ and 1D″. And along the second direction Y, the comb teeth 1121A of the comb-type pins 1121 on both sides of the second winding 112 are arranged in the same gap. And the “gap” refers to the gap between different rows of the switch elements 1221 in the same switch element group 122 or the gap between the switch elements 1221 and the edge of the rectifier board 120, i.e., in some embodiments of the disclosure, there is no switch element 1221 in the comb teeth 1121A of the comb-type pins 1121 on both sides of the second winding 112.

In an exemplary embodiment, as shown in FIG. 1D, the rectifier board 120 is provided with a first wire P along a first direction X, and a second wire Q along a second direction Y; the first wire P and the second wire Q are electrically connected to part of the switch elements, respectively. It should be noted that only a first wire P and a second wire Q are schematically drawn in the figure. In fact, it can be understood that the first wire P and the second wire Q can be set between different switch transistors, wherein the first wire P can be used as a power path, and the second wire Q can be used as a harmonic path. Because of the existence of the second wire Q, harmonics can have multiple paths to flow, thereby reducing the influence of the proximity effect between the wires, reducing the current loss on the rectifier board, and improving the overall power supply efficiency. As shown in FIG. 1A-1D, the second wire Q is formed between two comb gaps 1121B arranged oppositely along the second direction Y.

In an exemplary embodiment, as shown in FIG. 1D, any of the switch element groups 122 includes four switch elements 1221, namely, a first switch element 1221A, a second switch element 1221B, a third switch element 1221C, and a fourth switch element 1221D. The first switch element 1221A, the second switch element 1221B, the third switch element 1221C, and the fourth switch element 1221D are arranged along the second direction Y Two comb teeth 1121A of the comb-type pins 1121 are arranged on opposite sides of the second winding 112, and are respectively arranged between the first switch element 1221A and the second switch element 1221B, and between the third switch element 1221C and the fourth switch element 1221D. The second winding 112 inputs the alternating current into the rectifier circuit formed by the switch element group 122 through the two correspondingly arranged comb teeth 1121A for rectification. The so-called corresponding arrangement means that in space, multiple comb teeth between the same or different windings correspond one to one. As shown in FIGS. 1B and 1D, for the pins 1121 of the same second winding 112, along the second direction Y, the adjacent comb teeth of the same switch element group correspond to each other. As shown in 6B, the comb teeth of different first sub-windings 612A and second sub-windings 612B correspond to each other. In addition, due to process or actual manufacturing needs, the so-called corresponding arrangement of comb teeth does not mean that the corresponding comb teeth must be aligned. In some embodiments, the corresponding comb teeth may also be misaligned with each other, as shown in FIG. 2C.

In an exemplary embodiment, as shown in FIG. 1D, each switch element 1221 in the switch element group 122 is formed into a rectifier circuit by the first wire P and the second wire Q according to a bridge rectifier circuit. The four switches of the same switch element group 122 form a switch unit of a full-bridge rectifier circuit. In the embodiment, the bridge rectifier circuit is a rectifier circuit well known to those skilled in the art, and its specific circuit structure is not described in detail here. Those skilled in the art use other rectifier circuit structures well known in the art to connect the circuit of the switch element group 122, which should also be within the scope of protection of the present disclosure.

The difference between the embodiment shown in FIG. 1D′ and FIG. 1D is that the positions of the comb teeth 1121A of the comb-type pins 1121 on the two sides of the second winding 112 are different, wherein along the second direction Y, there is only one switch element 1221 between the comb teeth 1121A of the comb-type pins 1121 on the two sides of the second winding 112. The difference between the embodiment shown in FIG. 1D″ and FIG. 1D is that the positions of the comb teeth 1121A of the comb-type pins 1121 on the two sides of the second winding 112 are different, wherein along the second direction Y, there are three switch elements 1221 between the comb teeth 1121A of the comb-type pins 1121 on the two sides of the second winding 112. In other embodiments of the present disclosure, along the second direction Y, the number of switch elements 1221 between the comb teeth 1121A of the comb-type pins 1121 on the two sides of the second winding 112 can be flexibly adjusted according to actual needs.

In an exemplary embodiment, along the first direction X, at least one row of the switch elements 1221 (e.g., the first switch elements 1221A shown in FIG. 1D) is directly electrically connected to the comb-type pins 1121. That is, the switch elements 1221 and the comb-type pins 1121 may be directly electrically connected without other components such as capacitors and resistors.

In an exemplary embodiment, on the circuit board 121, the plurality of switch element groups 122 may be electrically connected in series or in parallel. Some switch elements of each switch element group 122 are also electrically connected through the aforementioned first wire P and second wire Q, wherein the potential at the connection point between the first wire P or the second wire Q and the switch element is the same.

FIG. 1F is a schematic diagram of the assembly of the rectifier module of the first embodiment of the present disclosure, wherein the transformer 110 and the rectifier board 120 are assembled into the rectifier module 100 as shown in the figure. In the embodiment, each switch element group 122 is located on a side close to the transformer 110.

In an exemplary embodiment, at least one output capacitor group 125 is further provided on the circuit board 121, as shown in the dotted box of FIG. 1F. The output capacitor groups 125 are arranged along the second direction Y The output capacitor group 125 includes a plurality of output capacitors. The output capacitors in the same output capacitor group 125 are arranged along the first direction X. The switch element groups 122 are connected to the output terminal through the output capacitor group 125, and the rectified current is output to the load through the output terminal.

In an exemplary embodiment, as shown in FIG. 1D, a plurality of driving resistors 1222 are further disposed on the circuit board 121. The plurality of driving resistors 1222 are disposed adjacent to corresponding switch elements 1221 for turning on corresponding switch elements 1221. The plurality of driving resistors 1222 are arranged along the first direction X or the second direction Y In this embodiment, the driving resistors 1222 and the switch elements 1221 correspond one to one, and in other embodiments of the present disclosure, one driving resistor 1222 may be connected to a plurality of switch elements 1221.

In an exemplary embodiment, as shown in FIG. 1G, an output terminal 123 is also provided on the circuit board 121. The rectifier board 120 is connected to the output terminal 123 through a conductive sheet 124, thereby being electrically connected to an external device. Thus, the AC power output by the transformer 110 in the present disclosure does not need to be transmitted to the external device through the main board 127 after being rectified by the switch element group 122. FIG. 1G′ is a schematic structural diagram of a partial cross-section of the conductive sheet 124 of the present embodiment. As shown in the dotted frame part in the figure, the conductive sheet 124 is directly electrically connected to the output terminal 123. Through the design of the output terminal 123, the transmission path of the output signal of the large current is shortened, and the energy loss of the output signal during the transmission process is effectively reduced. In some embodiments of the present disclosure, the conductive sheet 124 can be a copper busbar. The structure of the conductive sheet 124 connected between the rectifier board 120 and the output terminal 123 can be implemented in many ways. The above FIG. 1G is a schematic implementation structure. Those skilled in the art may design structures of the conductive sheets 124 that are compatible with the actual structural requirements, which should all be considered to be within the protection scope of the present disclosure.

It should be understood that in FIG. 1G, there are two rectifier boards 120, which are respectively disposed on both sides of the transformer 110 and are perpendicular to the main board 127. In some other embodiments of the present disclosure, there may be only one rectifier board 120, and at least a portion of the rectifier board 120 is disposed below the transformer 110. Further, the main board 127 and the rectifier board 120 may be integrally formed, that is, the main board 127 and the rectifier board 120 are the same plate, and the rectifier board 120 is an area on the main board 127.

In the rectifier module and transformer provided by the embodiments of the present disclosure, by designing the pins that connect the second winding to the rectifier board to be comb-type pins, the comb-type pins include a plurality of comb teeth and comb gaps arranged adjacent to the comb teeth. The comb teeth are arranged along a first direction. At the same time, in coordination with the circuit design of the switch element group of the rectifier board, the switch elements of the same switch element group are arranged along a second direction perpendicular to the direction of the comb teeth. Thus, a first wire P along the first direction and a second wire Q along the second direction are formed on the rectifier board. By leaving gaps between the switch elements of adjacent switch element groups, a path is provided for alternating current, thereby reducing the influence of the proximity effect between the wires, reducing the current loss on the rectifier board, and improving the overall power supply efficiency.

Referring to FIGS. 2A, 2B and 2C, FIG. 2A is a schematic diagram of the structure of the rectifier module of the second embodiment of the present disclosure, and FIG. 2B is a schematic diagram of the structure of the transformer of the second embodiment of the present disclosure. FIG. 2C is a schematic diagram of the structure of the rectifier board of the second embodiment of the present disclosure. The difference between this second embodiment and the aforementioned first embodiment lies in the structure of the second winding of the transformer. The other parts are similar to those of the first embodiment and will not be repeated here.

As shown in FIG. 2A, the rectifier module 200 includes: a transformer 210 and a rectifier board 220. The transformer 210 includes: a magnetic core 213, a first winding 211 and a second winding 212. The rectifier board 220 is a circuit board including a plurality of switch element groups. The rectifier board 220 is electrically connected to the transformer 210. It should be noted that, for the sake of simplicity, the switch elements on the rectifier board 220 are not shown in the figure, and the rectifier board 220 here is only used for illustration. In addition, in other embodiments of the present disclosure, a substrate (not shown in the figure) may be provided between the transformer 210 and the rectifier board 220, and a through hole is provided on the substrate for the comb-type pins of the second winding 212 to pass through, so as to fix the second winding 212.

As shown in FIG. 2B, the transformer 210 includes: a magnetic core 213, a first winding 211 and a second winding 212. The first winding 211 is formed of a coil for receiving input alternating current. The magnetic core 213 includes a magnetic column, and the coil forming the first winding 211 is arranged on the magnetic column, and the magnetic core 213 is mainly used for magnetic conduction. The second winding 212 is a coil group formed of multiple coils in parallel. Each coil has two side pins arranged oppositely. The two side pins of each parallel coil respectively form the comb pins 2121 of the second winding 212 (as shown in the dotted box in the figure). The comb pins 2121 of each coil are arranged along the first direction X. The transformer 210 is electrically connected to the rectifier board 220 through the comb pins 2121. In other embodiments of the present disclosure, the multiple coils of the second winding 212 can also be connected in series to form a coil group.

The so-called corresponding arrangement refers to the one-to-one correspondence of multiple comb teeth between the same or different windings in space, such as the corresponding arrangement along the second direction Y However, due to the process or actual manufacturing requirements, the so-called corresponding arrangement of comb teeth does not mean that the corresponding comb teeth must be aligned. As shown in FIG. 2C, since the coil forming the second winding 212 is a multi-turn coil, its two pins 2121A are offset to a certain extent along the first direction X. Therefore, the second wire Q (not shown in the figure) arranged along the second direction Y is not necessarily parallel to the second direction Y, and it only needs to be formed between the combs of the second winding 212 that are oppositely arranged.

Referring to FIGS. 3A, 3B, 3C, 3C′, 3D, 3D′, 3E, 3F, and 3G, FIG. 3A is a schematic diagram of the structure of the rectifier module of the third embodiment of the present disclosure, FIG. 3B is a schematic diagram of the structure of the transformer of the third embodiment of the present disclosure, FIG. 3C is a schematic diagram of the structure of the rectifier board of the third embodiment of the present disclosure, FIG. 3C′ is a schematic diagram of the structure of the other side of the rectifier board shown in FIG. 3C, FIG. 3D is a schematic diagram of the structure of the rectifier board of the third embodiment of the present disclosure, FIG. 3D′ is a schematic diagram of the structure of the other side of the rectifier board shown in FIG. 3D, FIG. 3E is a schematic diagram of the structure of the rectifier board of the third embodiment of the present disclosure, FIG. 3F is an assembly diagram of the rectifier module of the third embodiment of the present disclosure, and FIG. 3G is a schematic diagram of the structure of the rectifier module of the third embodiment of the present disclosure mounted with output terminals. The difference between this third embodiment and the aforementioned first embodiment lies in the structure of the second winding of the transformer and the layout structure of the corresponding switch element group in the rectifier board. The other parts are similar to the first embodiment and will not be repeated here.

As shown in FIG. 3A, the rectifier module 300 includes: a transformer 310 and a rectifier board 320. The transformer 310 includes: a magnetic core 313, a first winding 311 and a second winding 312. The rectifier board 320 is a circuit board including a plurality of switch element groups. The rectifier board 320 is electrically connected to the transformer 310. It should be noted that, for the sake of simplicity, the switch elements on the rectifier board 320 are not shown in the figure, and the rectifier board 320 here is only used for illustration. In addition, in other embodiments of the present disclosure, a substrate (not shown in the figure) may be provided between the transformer 310 and the rectifier board 320, and a through hole is provided on the substrate for the comb-type pins of the second winding 312 to pass through, so as to fix the second winding 312. FIG. 3F is an assembly schematic diagram of the rectifier module of the third embodiment of the present disclosure, and the transformer 310 and the rectifier board 320 are assembled into the rectifier module 300 as shown in the figure.

As shown in FIG. 3B and FIG. 3C, the transformer 310 includes: a magnetic core 313, a first winding 311 and a second winding 312. The first winding 311 is formed of a coil and is used to receive input alternating current. The magnetic core 313 includes a magnetic column, and the coil forming the first winding 311 is arranged on the magnetic column. The magnetic core 313 is mainly used for magnetic conduction. The second winding 312 includes a first sub-winding 312A and a second sub-winding 312B. The first sub-winding 312A is arranged outside the first winding 311. The second sub-winding 312B is arranged outside the first sub-winding 312A. Comb-type pins 3121 of the second winding 312 are respectively arranged on opposite sides of the first sub-winding 312A and the second sub-winding 312B. The comb-type pins 3121 include comb teeth 3121A and comb gaps 3121B arranged adjacent to the comb teeth 3121A. The comb-type pins 3121 are arranged along the first direction X. Taking the first sub-winding 321A as an example, the comb-type pins 3121 include at least two comb teeth 3121A′, and a comb gap 3121B′ is arranged adjacent to the comb teeth 3121A′. It should be noted here that the comb gap 3121B′ is adjacent to the comb teeth 3121A′, and the comb gap 3121B′ is not necessarily between the two comb teeth 3121A′, such as the comb teeth 3121A′ and the comb gap 3121B′ at the edge of the comb-type pin in FIG. 3B. The second sub-winding 321B is similar to the first sub-winding 321A, and will not be repeated here. The comb teeth 3121A′ of the first sub-winding 312A and the comb teeth 3121A″ of the second sub-winding 312B are interlaced. The so-called interlaced arrangement means that the comb teeth 3121A′ of the first sub-winding 312A are arranged correspondingly to the comb gaps 3121B″ of the second sub-winding 312B, and the comb teeth 3121A″ of the second sub-winding 312B are arranged correspondingly to the comb gaps 3121B′ of the first sub-winding 312A. At least part of the second wire Q is formed between the comb gaps that are oppositely arranged along the second direction Y of the second winding 312, wherein the second wire Q is arranged on the circuit board 312. Specifically, the second wire Q is formed between the oppositely arranged comb gaps 3121B′ of the first sub-winding 312A, or between the oppositely arranged comb gaps 3121B″ of the second sub-winding 312B. The comb teeth 3121A′ of the first sub-winding 312A and the comb teeth 3121B″ of the second sub-winding 312B can be completely staggered or partially overlapped, as long as an electrically connected channel is formed between the corresponding comb teeth 3121A′ or 3121A″ along the second direction Y, that is, the second wire Q for the current harmonic to flow through, it should be considered within the protection scope of the present disclosure. The transformer 310 is electrically connected to the rectifier board 320 through the comb teeth 3121A′ of the first sub-winding 312A and the comb teeth 3121A″ of the second sub-winding 312B.

In an exemplary embodiment, as shown in FIGS. 3C and 3C′, the rectifier board 320 includes: a circuit board 321 and a plurality of switch element groups 322. The circuit board 321 includes a first surface 321A and a second surface 321B that are arranged opposite to each other. The plurality of switch element groups 322 are arranged on the circuit board 321. The plurality of switch element groups 322 are arranged along the first direction X, and are used to rectify the output current of the second winding 312.

In the embodiment, the same switch element group 322 includes a first switch element 3221A and a second switch element 3221B. The first switch element 3221A is located on the first surface 321A of the circuit board 321. The second switch element 3221B is located on the second surface 321B of the circuit board 321. The first switch element 3221A and the second switch element 3221B do not overlap along the second direction Y, and are arranged along the first direction X, that is, they are staggered and spaced. Along the first direction, the first switch element 3221A and the second switch element 3221B can be completely staggered or partially overlapped, as long as the corresponding comb teeth 3121A can be staggered, which should be considered within the protection scope of the present disclosure. Along the second direction Y, the comb-type pins 3121 on the two sides of the first sub-winding 312A and the second sub-winding 312B are respectively located outer side the first switch element 3221A and the second switch element 3221B, and are electrically connected to the rectifier board 320 through the corresponding comb teeth 3121A. On the circuit board 321, a first wire P is arranged along the first direction X, and a second wire Q is arranged along the second direction Y The first wire P and the second wire Q are respectively electrically connected to part of the first switch element 3221A and the second switch element 3221B, and connect respective switch elements to form a rectifier circuit, wherein the potential of the connection points between first wire P or the second wire Q and switch element is the same. The first direction X and the second direction Y are perpendicular to each other. In addition, in the embodiment shown in FIG. 3C, one first switch element 3221A or one second switch element 3221B can correspond to multiple comb teeth 3121A′ and 3121A″.

It is understandable that, in other embodiments of the present disclosure, when the same switch element group 322 includes more than two switch elements, it is only necessary to ensure that there is at least one switch element on each side of the circuit board 321.

In an exemplary embodiment, as shown in FIGS. 3D and 3D′, the rectifier board 320 includes: a circuit board 321 and a plurality of switch element groups 322. The circuit board 321 includes a first surface 321A and a second surface 321B that are arranged opposite to each other. The plurality of switch element groups 322 are arranged on the circuit board 321. The plurality of switch element groups 322 are arranged along the first direction X, and are used to rectify the output current of the second winding 312.

In the embodiment, the same switch element group 322 includes a first switch element 3221A and a second switch element 3221B. The first switch element 3221A is located on the first surface 321A of the circuit board 321. The second switch element 3221B is located on the second surface 321B of the circuit board 321. The first switch element 3221A and the second switch element 3221B at least partially overlap along the second direction Y, and are interlaced along the first direction X. Taking FIG. 3D as an example, the first switch element 3221A and the second switch element 3221B completely overlap along the second direction Y, but in other embodiments of the present disclosure, the first switch element 3221A and the second switch element 3221B may also have a certain misalignment along the second direction Y Along the second direction Y, the comb-type pins 3121 on the two sides of the first sub-winding 312A and the second sub-winding 312B are respectively located at outer side the first switch element 3221A and the second switch element 3221B, and are electrically connected to the rectifier board 320 through the corresponding comb teeth 3121A. On the circuit board 321, a first wire P is arranged along the first direction X, and a second wire Q is arranged along the second direction Y The first wire P and the second wire Q are respectively electrically connected to part of the first switch element 3221A and the second switch element 3221B, and the switch elements are connected to form a rectifier circuit, wherein the potential of the connection points between first wire P or the second wire Q and switch element is the same. The first direction X and the second direction Y are perpendicular to each other.

It should be noted that in some embodiments of the present disclosure, in FIGS. 3D and 3D′, the switch element group 322 may not be centrally disposed on the circuit board 321 in the second direction Y, so as to reserve a position for a capacitor (not shown) disposed on the circuit board 321.

In an exemplary embodiment, as shown in FIG. 3E, the rectifier board 320 includes: a circuit board 321 and a plurality of switch element groups 322. The plurality of switch element groups 322 are disposed on the same surface of the circuit board 321. The plurality of switch element groups 322 are arranged along the first direction X, and are used to rectify the output current of the second winding 312.

In the embodiment, the same switch element group 322 includes a first switch element 3221A and a second switch element 3221B. The first switch element 3221A and the second switch element 3221B are located on the same surface of the circuit board 321. The first switch element 3221A and the second switch element 3221B do not overlap along the second direction Y, and are arranged along the first direction X, that is, they are staggered and spaced. In the embodiment, along the first direction, the first switch element 3221A and the second switch element 3221B can be completely staggered or partially overlapped, as long as the corresponding comb teeth 3121A can be staggered, which should be considered within the protection scope of the present disclosure. Along the second direction Y, the comb-type pins 3121 on both sides of the first sub-winding 312A and the second sub-winding 312B are respectively located on the outer side of the first switch element 3221A and the second switch element 3221B, and are electrically connected to the rectifier board 320 through the correspondingly arranged comb teeth 3121A. On the circuit board 321, a first wire P is arranged along the first direction X, and a second wire Q is arranged along the second direction Y The first wire P and the second wire Q are electrically connected to part of the first switch element 3221A and the second switch element 3221B respectively, and the switch elements are connected to form a rectifier circuit, wherein the potential of the connection points between first wire P or the second wire Q and switch element is the same. The first direction X and the second direction Y are perpendicular to each other. Moreover, similar to FIG. 3C, in the embodiment shown in FIG. 3E, a first switch element 3221A or a second switch element 3221B can correspond to a plurality of comb teeth 3121A′ and 3121A″.

FIG. 3G is a schematic diagram of the structure of the rectifier module mounted with output terminals of the third embodiment of the present disclosure, which differs from the embodiment shown in FIG. 1G in the structure of the conductive sheet 124, the structure of the second winding of the transformer, and the layout structure of the corresponding switch element group in the rectifier board. The other parts are similar to the embodiment shown in FIG. 1G and are not repeated here. The structure of the conductive sheet 124 connected between the rectifier board 120 and the output terminal 123 can be implemented in many ways. FIG. 3G above shows a schematic implementation structure. Those skilled in the art design a structure of the conductive sheet 124 that is compatible with the actual structural requirements, which should be regarded as within the scope of protection of the present disclosure.

In an exemplary embodiment, the respective switch elements 3221 in the switch element group 322 shown in FIG. 3C and FIG. 3D are formed into a rectifier circuit by the first wire P and the second wire Q according to the center-tapped rectifier circuit. Two switches of the same switch element group 322 form a switch unit of a center-tapped rectifier circuit. In the embodiment, the center-tapped rectifier circuit is a rectifier circuit well known to those skilled in the art, and its specific circuit structure is not described in detail here. Those skilled in the art use other rectifier circuit structures well known in the art to connect the circuit of the switch element group 322, which should also be within the scope of protection of the present disclosure.

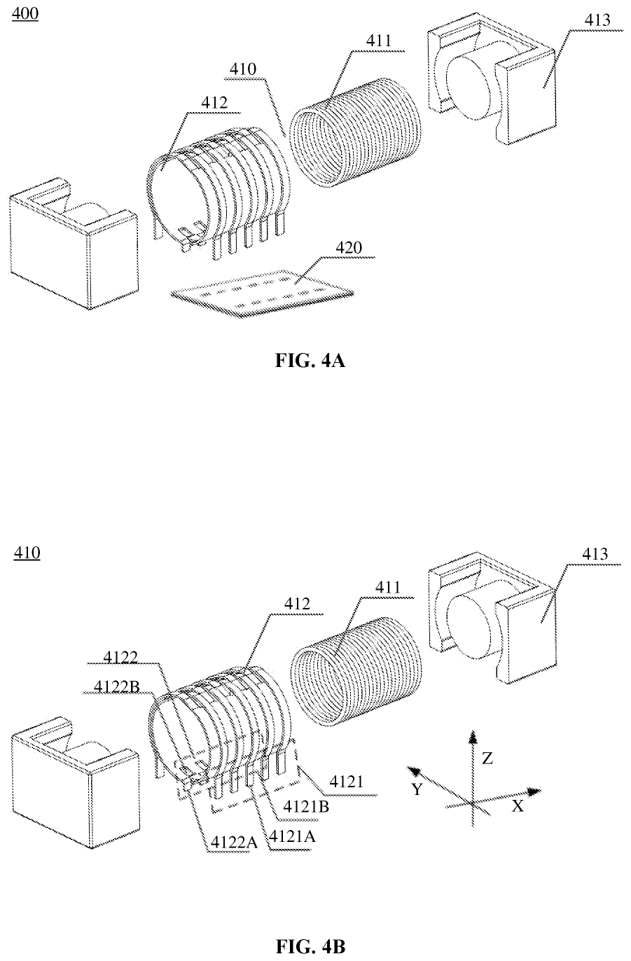

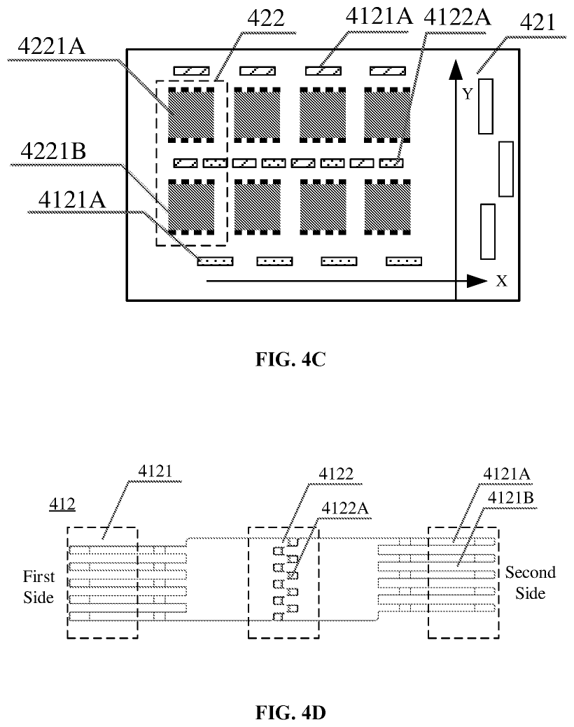

Referring to FIGS. 4A, 4B, 4C and 4D, FIG. 4A is a schematic diagram of the structure of the rectifier module of the fourth embodiment of the present disclosure, FIG. 4B is a schematic diagram of the structure of the transformer of the fourth embodiment of the present disclosure, FIG. 4C is a schematic diagram of the structure of the rectifier board of the fourth embodiment of the present disclosure, and FIG. 4D is a schematic diagram of the second winding of the fourth embodiment of the present disclosure. The difference between this fourth embodiment and the aforementioned first embodiment lies in the structure of the second winding of the transformer and the layout structure of the corresponding switch element group in the rectifier board. The other parts are similar to those of the first embodiment and will not be repeated here.

As shown in FIG. 4A, the rectifier module 400 includes a transformer 410 and a rectifier board 420. The transformer 410 includes a magnetic core 413, a first winding 411 and a second winding 412. The rectifier board 420 is a circuit board including a plurality of switch element groups. The rectifier board 420 is electrically connected to the transformer 410.

As shown in FIG. 4B, the transformer 410 includes: a magnetic core 413, a first winding 411 and a second winding 412. The first winding 411 is formed of a coil and is used to receive input alternating current. The magnetic core 413 includes a magnetic column, and the coil forming the first winding 411 is arranged on the magnetic column, and the magnetic core 413 is mainly used for magnetic conduction. A first group of interlaced comb-type pins 4121 are formed on opposite sides of the second winding along the second direction Y The first group of interlaced comb-type pins 4121 includes two rows of comb-type pins, and each row of comb-type pins is arranged along the first direction X. In the embodiment, each row of comb-type pins of the first group of interlaced comb-type pins 4121 includes at least two comb teeth 4121A, and a comb gap 4121B is arranged adjacent to the comb teeth 4121A. The comb teeth 4121A on the first side of the second winding pass through the comb gaps 4121B on the second side of the second winding and extend along the third direction Z. The comb teeth 4121A on the second side of the second winding pass through the comb gaps 4121B on the first side of the second winding and extend along the third direction Z. In addition to the above-mentioned first group of interlaced comb pins 4121, a second group of interlaced comb pins 4122 along the first direction X is formed between the first side and the second side of the second winding. The second group of interlaced comb-type pins 4122 may include two rows of comb-type pins along the second direction Y, or may be arranged only along the first direction X, as shown in FIG. 4C. However, in fact, the function of the comb-type pins 4122 is the same as that of the two rows of comb-type pins, and the number of comb teeth is the same. It is just that the arrangement positions of the two rows of comb-type pins are deviated in the second direction. As shown in FIG. 4C, the comb teeth 4122A include two types of oblique line shadows and dotted line shadows, which correspond to the two rows of comb-type pins, respectively. Therefore, for the convenience of description, this situation is also referred to as two rows of comb-type pins. The second group of interlaced comb-type pins 4122 are arranged along the first direction X. Each row of comb-type pins of the second group of interlaced comb-type pins 4122 includes at least two comb teeth 4122A, and a comb gap 4122B is arranged adjacent to the comb teeth 4122A. The comb teeth 4122A in the second group of interlaced comb pins 4122 are arranged correspondingly to the comb teeth 4121A in the first group of interlaced comb pins 4121. The first direction X, the second direction Y and the third direction Z are perpendicular to each other. The transformer 410 is electrically connected to the rectifier board 420 through the comb teeth 4121A in the first group of interlaced comb pins 4121 and the comb teeth 4122A in the second group of interlaced comb pins 4122. The so-called first group of interlaced comb pins or the second group of interlaced comb pins means that in each group of comb pins, the comb teeth of one row of the two rows of comb pins are arranged correspondingly to the comb gaps of the other row. The so-called comb teeth 4122A in the second group of interlaced comb pins 4122 are arranged correspondingly to the comb teeth 4121A in the first group of interlaced comb pins 4121, means that the comb teeth of a row of comb pins in the first group of interlaced comb pins 4121 correspond to the comb teeth of a row of comb pins in the second group of interlaced comb pins 4122, as shown in FIGS. 4A-4C. The second group of interlaced comb pins is used to form the center tap of the center-tapped rectifier transformer.

As shown in FIG. 4D, the second winding 412 is, for example, a metal sheet. The opposite sides of the metal sheet are the first side and the second side of the second winding 412, and a first group of interlaced comb-type pins 4121 are respectively arranged on the two sides, which include comb teeth 4121A and comb gaps 4121B arranged adjacent to the comb teeth 4121A. The first group of interlaced comb-type pins 4121 on the two sides are arranged alternately, so that the comb teeth 4121A on the first side can pass through the comb gaps 4121B on the second side; and the comb teeth 4121A on the second side can pass through the comb gaps 4121B on the first side. Between the opposite sides of the second winding 412, for example, in the middle of the metal sheet, a second group of interlaced comb-type pins 4122 are also arranged along the first direction X. Each row of comb pins of the second group of interlaced comb pins 4122 includes at least two comb teeth 4122A, and a comb gap 4122B is disposed adjacent to the comb teeth 4122A. The comb teeth 4122A in the second group of interlaced comb pins 4122 are disposed correspondingly to the comb teeth 4121A in the first group of interlaced comb pins 4121.

As shown in FIG. 4C, the rectifier board 420 includes: a circuit board 421 and a plurality of switch element groups 422. The plurality of switch element groups 422 are disposed on the circuit board 421. The plurality of switch element groups 422 are arranged along the first direction X, and are used to rectify the output current of the second winding 412.

In the embodiment, the same switch element group 422 includes a first switch element 4221A and a second switch element 4221B. In the second direction Y, the comb teeth 4121A on the first and second sides of the first group of interlaced comb pins 4121 of the second winding are respectively located at the outer side the first switch element 4221A and the second switch element 4221B. Similarly, along the second direction Y, the comb teeth 4122A in the second group of interlaced comb pins 4122 of the second winding are located between the first switch element 4221A and the second switch element 4221B. The second winding 412 is electrically connected to the rectifier board 420 through the comb teeth 4121A and 4122A. On the circuit board 421, a first wire P is arranged along the first direction X, and a second wire Q is arranged along the second direction Y The first wire P and the second wire Q are electrically connected to part of the first switch element 4221A and part of the second switch element 4221B respectively, and the switch elements are connected to form a rectifier circuit, wherein the potential of the connection points between first wire P or the second wire Q and switch element is the same. The first direction X and the second direction Y are perpendicular to each other.

Referring to FIGS. 5A, 5B, and 5C, FIG. 5A is a schematic diagram of the structure of the rectifier module of the fifth embodiment of the present disclosure, and FIG. 5B is a schematic diagram of the structure of the transformer of the fifth embodiment of the present disclosure. FIG. 5C is an assembly diagram of the rectifier module of the fifth embodiment of the present disclosure. The difference between this fifth embodiment and the aforementioned first embodiment lies in the structure of the second winding of the transformer. The other parts are similar to those of the first embodiment and will not be repeated here.

As shown in FIG. 5A, the rectifier module 500 includes: a transformer 510 and a rectifier board 520. The transformer 510 includes: a magnetic core 513, a first winding 511 and a second winding 512. The rectifier board 520 is a circuit board including a plurality of switch element groups. The rectifier board 520 is electrically connected to the transformer 510. FIG. 5C is an assembly diagram of the rectifier module of the fifth embodiment of the present disclosure, and the transformer 510 and the rectifier board 520 are assembled into the rectifier module 500 as shown in the figure.

As shown in FIG. 5B, the transformer 510 includes: a magnetic core 513, a first winding 511 and a second winding 512. The second winding 512 includes a first sub-winding 512A and a second sub-winding 512B. The first sub-winding 512A and the second sub-winding 512B are arranged on opposite sides of the first winding 511. Comb-type pins 5121 are respectively arranged on opposite sides of the first sub-winding 512A and the second sub-winding 512B. The comb-type pins 5121 are arranged along the first direction X. The comb-type pins 5121 include at least two comb teeth 5121A, and a comb gap 5121B is arranged adjacent to the comb teeth 5121A. The comb teeth 5121A of the first sub-winding 512A and the second sub-winding 512B are respectively arranged correspondingly. The transformer 510 is electrically connected to the rectifier board 520 through the comb teeth 5121A of the first sub-winding 512A and the second sub-winding 512B.

In the embodiment, the rectifier board 520 includes a first circuit board 521A and a second circuit board 521B. The comb teeth 5121A of the comb-type pins 5121 on one side of the first sub-winding 512A and the second sub-winding 512B are electrically connected to the first circuit board 521A. The comb teeth 5121A of the comb-type pins 5121 on the other side of the first sub-winding 512A and the second sub-winding 512B are electrically connected to the second circuit board 521B. The layout of the switch transistors of the first circuit board 521A and the second circuit board 521B is similar to that of FIG. 1D, and will not be repeated here.

Referring to FIGS. 6A, 6B, and 6C, FIG. 6A is a schematic diagram of the structure of the rectifier module of the sixth embodiment of the present disclosure, and FIG. 6B is a schematic diagram of the structure of the transformer of the sixth embodiment of the present disclosure. FIG. 6C is an assembly diagram of the rectifier module of the sixth embodiment of the present disclosure. The difference between this sixth embodiment and the aforementioned third embodiment lies in the structure of the second winding of the transformer. The other parts are similar to those of the third embodiment and will not be repeated here.

As shown in FIG. 6A, the rectifier module 600 includes: a transformer 610 and a rectifier board 620. The transformer 610 includes: a magnetic core 613, a first winding 611 and a second winding 612. The rectifier board 620 is a circuit board including a plurality of switch element groups. The rectifier board 620 is electrically connected to the transformer 610. FIG. 6C is an assembly diagram of the rectifier module of the sixth embodiment of the present disclosure, wherein the transformer 610 and the rectifier board 620 are assembled into the rectifier module 600 as shown in the figure.

As shown in FIG. 6B, the transformer 610 includes: a magnetic core 613, a first winding 611 and a second winding 612. The second winding 612 includes a first sub-winding 612A, a second sub-winding 612B, a third sub-winding 612C and a fourth sub-winding 612D. The first sub-winding 612A and the second sub-winding 612B are arranged on two sides of the first winding 611. The third sub-winding 612C and the fourth sub-winding 612D are respectively arranged outside the first sub-winding 612A and the second sub-winding 612B and are arranged opposite to each other. Comb-type pins 6121 are respectively arranged on opposite sides of the first sub-winding 612A, the second sub-winding 612B, the third sub-winding 612C and the fourth sub-winding 612D. The comb-type pins 6121 are arranged along the first direction X. The comb-type pin 6121 includes at least two comb teeth 6121A, and a comb gap 6121B is arranged adjacent to the comb teeth 6121A. The comb teeth 6121A of the first sub-winding 612A and the second sub-winding 612B are respectively arranged correspondingly. The comb teeth 6121A of the third sub-winding 612C and the fourth sub-winding 612D are respectively arranged correspondingly. The comb teeth 6121A of the first sub-winding 612A and the third sub-winding 612C are interlaced. The comb teeth 6121A of the second sub-winding 612B and the fourth sub-winding 612D are interlaced. The so-called interlaced arrangement means that the comb teeth of the winding correspond to the comb gap of the corresponding winding. The transformer 610 is electrically connected to the rectifier board 620 through the comb teeth 6121A of the first sub-winding 612A, the second sub-winding 612B, the third sub-winding 612C and the fourth sub-winding 612D.

In the embodiment, the rectifier board 620 includes a first circuit board 621A and a second circuit board 621B. The comb teeth 6121A of the comb-type pins 6121 on one side of the first sub-winding 612A, the second sub-winding 612B, the third sub-winding 612C and the fourth sub-winding 612D are electrically connected to the first circuit board 621A. The comb teeth 6121A of the comb-type pins 6121 on the other side of the first sub-winding 612A, the second sub-winding 612B, the third sub-winding 612C and the fourth sub-winding 612D are electrically connected to the second circuit board 621B. The layout of the switch tubes of the first circuit board 621A and the second circuit board 621B is similar to that of FIGS. 3C and 3D, and will not be repeated here.

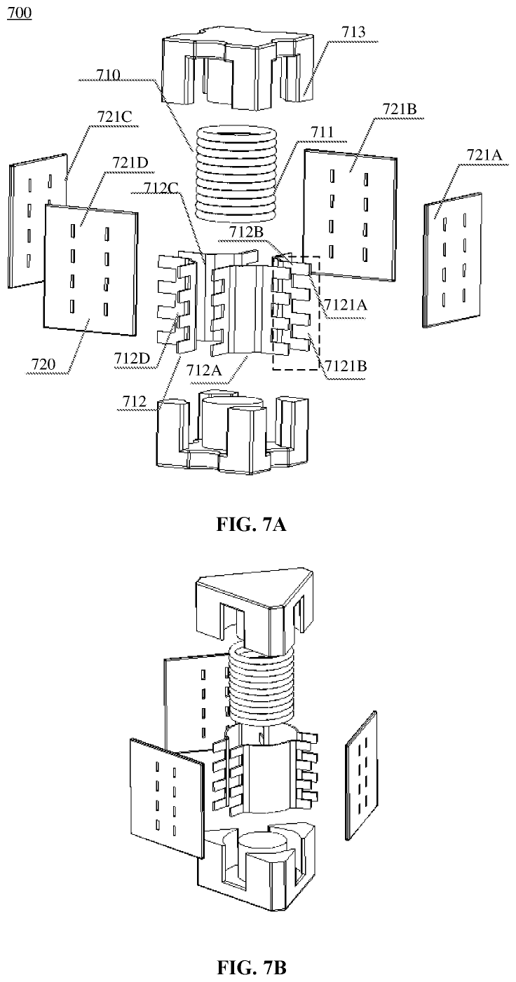

Referring to FIGS. 7A and 7B, FIG. 7A is a schematic diagram of the structure of the rectifier module of the seventh embodiment of the present disclosure. FIG. 7B is a schematic diagram of the structure of the rectifier module of the seventh embodiment of the present disclosure. The difference between the seventh embodiment and the aforementioned first embodiment lies in the structure of the second winding of the transformer. The other parts are similar to the first embodiment and will not be repeated here.

As shown in FIG. 7A, the rectifier module 700 includes a transformer 710 and a rectifier board 720. The transformer 710 includes a magnetic core 713, a first winding 711 and a second winding 712. The rectifier board 720 is a circuit board including a plurality of switch element groups. The rectifier board 720 is electrically connected to the transformer 710.

As shown in FIG. 7A, the transformer 710 includes: a magnetic core 713, a first winding 711 and a second winding 712. The second winding 712 includes a first sub-winding 712A, a second sub-winding 712B, a third sub-winding 712C and a fourth sub-winding 712D. The first sub-winding 712A, the second sub-winding 712B, the third sub-winding 712C and the fourth sub-winding 712D are sequentially arranged on the circumference of the first winding 711. Comb-type pins 7121 are respectively provided on opposite sides of the first sub-winding 712A, the second sub-winding 712B, the third sub-winding 712C and the fourth sub-winding 712D. The comb-type pins 7121 are arranged along the first direction X. The comb-type pins 7121 include at least two comb teeth 7121A, and a comb gap 7121B is provided adjacent to the comb teeth 7121A. The comb teeth 7121A adjacent to the first sub-winding 712A and the second sub-winding 712B are respectively arranged correspondingly; the comb teeth 7121A adjacent to the second sub-winding 712B and the third sub-winding 712C are respectively arranged correspondingly; the comb teeth 7121A adjacent to the third sub-winding 712C and the fourth sub-winding 712D are respectively arranged correspondingly; the comb teeth 7121A adjacent to the first sub-winding 712A and the fourth sub-winding 712D are respectively arranged correspondingly. The transformer 710 is electrically connected to the rectifier board 720 through the comb teeth 7121A of the first sub-winding 712A, the second sub-winding 712B, the third sub-winding 712C and the fourth sub-winding 712D.

In the embodiment, the rectifier board 720 includes a first circuit board 721A, a second circuit board 721B, a third circuit board 621C and a fourth circuit board 721D. The comb teeth 7121A corresponding to the first sub-winding 712A and the second sub-winding 712B are electrically connected to the first circuit board 721A; the comb teeth 7121A corresponding to the second sub-winding 712B and the third sub-winding 712C are electrically connected to the second circuit board 721B; the comb teeth 7121A corresponding to the third sub-winding 712C and the fourth sub-winding 712D are electrically connected to the third circuit board 721C; and the comb teeth 7121A corresponding to the fourth sub-winding 712D and the first sub-winding 712A are electrically connected to the fourth circuit board 721D. The layout of the switch tubes of the first circuit board 521A and the second circuit board 521B is similar to that of FIG. 1D, and will not be repeated here.

It should be noted that in the embodiments of the present disclosure, only the implementation scheme of 4 groups of second windings and 4 rectifier boards is used as an exemplary introduction. Based on this structural configuration, the implementation scheme of 3 groups of second windings and 3 rectifier boards (see FIG. 7B), the implementation scheme of 5 groups of second windings and 5 rectifier boards, the implementation scheme of 6 groups of second windings and 6 rectifier boards, etc. can also be adopted, all of which are used to realize full-bridge rectification. The relevant implementation schemes should also be regarded as within the protection scope of the present disclosure. In addition, as in the aforementioned embodiment six, the embodiments of the present disclosure can also realize extended embodiments such as 8 groups of second windings and 4 rectifier boards, and the combination of 6 groups of second windings and 3 rectifier boards, all of which are used to realize center-tapped rectification. At this time, the layout of switch transistors of the rectifier board is similar to FIGS. 3C and 3D, and will not be repeated here.

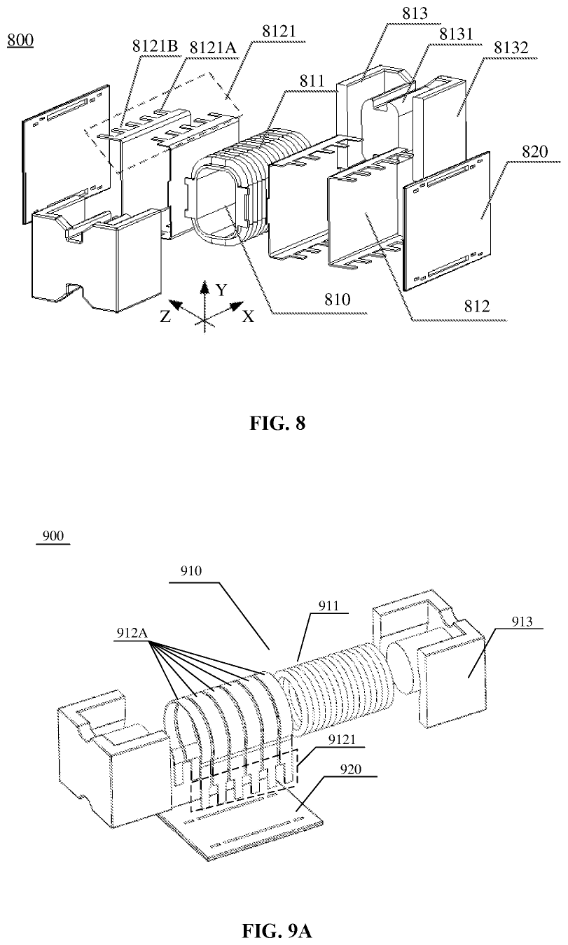

See FIG. 8, which is a schematic diagram of the structure of the rectifier module of the eighth embodiment of the present disclosure. The difference between the eighth embodiment and the aforementioned third embodiment lies in the structure of the second winding of the transformer. The other parts are similar to the third embodiment and will not be repeated here.

As shown in FIG. 8, the rectifier module 800 includes a transformer 810 and a rectifier board 820. The transformer 810 includes a magnetic core 813, a first winding 811 and a second winding 812. The rectifier board 820 is a circuit board including a plurality of switch element groups. The rectifier board 820 is electrically connected to the transformer 810.

As shown in FIG. 8, the magnetic column of the magnetic core 813 includes a middle column 8131 and at least two side columns 8132. The first winding 811 is arranged on the middle column 8131, and the second winding 812 is arranged on the side column 8132. Comb-type pins 8121 are respectively provided on opposite sides of the second winding 812. The comb-type pins 8121 are arranged along the first direction X. The comb-type pins 8121 include at least two comb teeth 8121A, and a comb gap 8121B is provided adjacent to the comb teeth 8121A. And along a third direction Z, the comb-type pins 8121 are extend away from the middle column 8131. The transformer 810 is electrically connected to the rectifier board 820 through the comb teeth 8121A of the second winding 812. In the embodiment, the layout of the circuit board switch tube is similar to that of FIG. 3C and FIG. 3D, and will not be repeated here. The third direction Z is perpendicular to the first direction X and the second direction Y.

As shown in FIG. 8, the second winding in the eighth embodiment may be similar to the fifth embodiment, including a pair of second windings arranged oppositely, or may be similar to the sixth embodiment, including two pairs of second windings arranged oppositely. The difference is that the second windings in the fifth and sixth embodiments are arranged on the first winding, while the second winding in the eighth embodiment is arranged on the side column. i.e., as the direction of the second winding in the eighth embodiment shown in FIG. 8, the second winding is wound on the side column. Other similar parts are not repeated here.

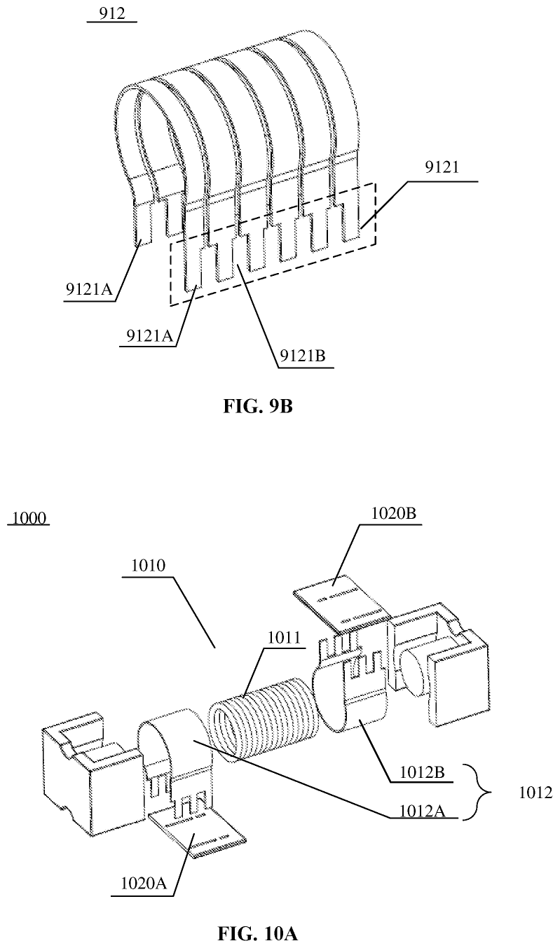

Referring to FIG. 9A and FIG. 9B, FIG. 9A is a schematic diagram of the structure of the rectifier module of the ninth embodiment of the present disclosure. FIG. 9B is a schematic diagram of the structure of the second winding of the ninth embodiment of the present disclosure. The difference between the ninth embodiment and the aforementioned first embodiment lies in the structure of the second winding of the transformer. The other parts are similar to the first embodiment and will not be repeated here.

As shown in FIG. 9A and FIG. 9B, the rectifier module 900 includes: a transformer 910 and a rectifier board 920. The transformer 910 includes: a magnetic core 913, a first winding 911 and a second winding 912. The rectifier board 920 is a circuit board including a plurality of switch element groups. The rectifier board 920 is electrically connected to the transformer 910. It should be noted that, for the sake of simplicity, the switch elements on the rectifier board 920 are not shown in the figure, and the rectifier board 920 here is only used for illustration. In addition, in other embodiments of the present disclosure, a substrate (not shown in the figure) can also be arranged between the transformer 910 and the rectifier board 920, and a through hole is provided on the substrate for the comb-type pins of the second winding 912 to pass through, so as to fix the second winding 912.

In this embodiment, the second winding 912 is not integrally formed, but is formed by splicing a plurality of separately disposed separate windings 912A, wherein each separate winding 912A includes at least two oppositely arranged comb teeth 9121A, and a plurality of separate windings 912A are spliced to form a comb-type pin 9121, wherein the comb-type pin 9121 includes a plurality of comb teeth 9121A and a plurality of comb gaps 9121B.

Specifically, as shown in FIG. 9B, the joint seams of the plurality of separate windings 912A may be formed in the middle of the comb gap 9121B of the comb-type legs 9121. In other embodiments, the joint seams may also be provided at other locations.

In the embodiment, at least two comb teeth 9121A of at least two separate windings 912A among the multiple separate windings 912A are in the same direction. In this embodiment, the direction of the comb teeth 9121A of each separate winding 912A is the same. However, in other embodiments of the present disclosure, if the second winding as shown in FIGS. 7A and 7B is configured as a separate winding 912A, the directions of the comb teeth 9121A of the multiple separate windings 912A may also be different.

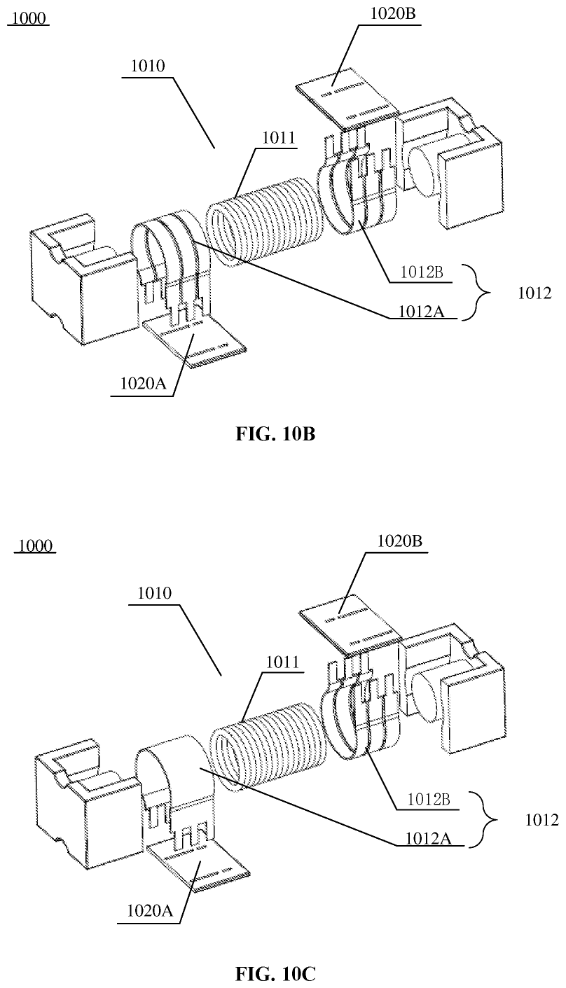

Referring to FIGS. 10A, 10B, and 10C, FIG. 10A is a structural schematic diagram 1 of a rectifier module of the tenth embodiment of the present disclosure. FIG. 10B is a structural schematic diagram 2 of a rectifier module of the tenth embodiment of the present disclosure. FIG. 10C is a structural schematic diagram 3 of a rectifier module of the tenth embodiment of the present disclosure. The difference between this tenth embodiment and the aforementioned first embodiment lies in the structure of the second winding of the transformer and the rectifier board. The other parts are similar to those of the first embodiment and will not be repeated here.

As shown in FIG. 10A to FIG. 10C, the rectifier module 1000 includes: a transformer 1010 and a rectifier board 1020. The transformer 1010 includes: a magnetic core 1013, a first winding 1011 and a second winding 1012. The rectifier board 1020 is a circuit board including a plurality of switch element groups. The rectifier board 1020 is electrically connected to the transformer 1010. It should be noted that, for the sake of simplicity, the switch elements on the rectifier board 1020 are not shown in the figure, and the rectifier board 1020 here is only used for illustration. In addition, in other embodiments of the present disclosure, a substrate (not shown in the figure) may be further provided between the transformer 1010 and the rectifier board 1020, and a through hole is provided on the substrate for the comb-type pins of the second winding 1012 to pass through, so as to fix the second winding 1012.

In the embodiment shown in FIG. 10A, the second winding 1012 includes a first separate winding 1012A and a second separate winding 1012B that are separately arranged, wherein the first separate winding 1012A and the second separate winding 1012B both include comb-type pins, and the comb-type pins of the first separate winding 1012A and the second separate winding 1012B have different directions. Correspondingly, the rectifier board 1020 includes a first separate rectifier board 1020A and a second separate rectifier board 1020B, wherein the comb-type pins of the first separate winding 1012A are arranged on the first separate rectifier board 1020A, and the comb-type pins of the second separate winding 1012B are arranged on the second separate rectifier board 1020B. It should be noted that the first separate winding 1012A and the second separate winding 1012B, the first separate rectifier board 1020A and the second separate rectifier board 1020B in this embodiment are different from the first winding 511, the second winding 512, the first circuit board 521A and the second circuit board 521B in the fifth embodiment. The first separate winding 1012A and the second separate winding 1012B in this embodiment are electrically connected to each other, and actually realize the function of one second winding 1012, and the first separate rectifier board 1020A and the second separate rectifier board 1020B are electrically connected to each other, and also realize the function of one rectifier board, but the separate setting changes the position layout of the second winding 1012 and the rectifier board 1020. Of course, in other embodiments of the present disclosure, the second winding 1012 may include three or more separate windings, and the rectifier board 1020 may also include three or more separate rectifier boards.

In some embodiments of the present disclosure, the first separate winding 1012A and/or the second separate winding 1012B may also be configured as the second winding 912 in the previous embodiments, as shown in FIGS. 10B and 10C, which will not be described in detail herein.

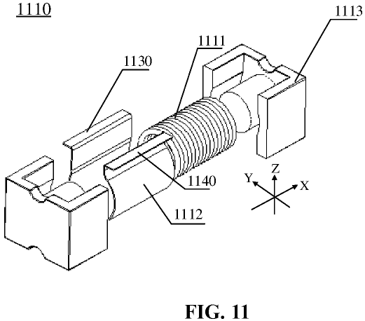

Referring to FIG. 11, FIG. 11 is a schematic diagram of the structure of a transformer according to the eleventh embodiment of the present disclosure. The difference between the eleventh embodiment and the aforementioned first embodiment lies in the second winding of the transformer.

As shown in FIG. 11, the transformer 1110 includes: a magnetic core 1113, a first winding 1111 and a second winding 1112. The first winding 1111 is formed of a coil and is used to receive input alternating current. The magnetic core 1113 includes a magnetic column, and the coil forming the first winding 1111 is arranged on the magnetic column. The magnetic core 1113 is mainly used for magnetic conduction. The second winding 1112 is arranged outside the first winding 1111. Bar-type first pins 1130 and 1140 are respectively arranged on opposite sides of the second winding 1112. The first pins 1130 and the second pins 1140 are arranged on the circuit board in a surface mounting manner. Along the second direction Y, the first pins 1130 and the second pins 1140 are adjacent to the switch element; the first direction X and the second direction Y are perpendicular to each other. It should be understood that the specific distribution of the first pin and the second pin of the transformer and the switch element in FIG. 11 is the same as the comb-type pins in the above embodiment, and will not be described in detail here.

In addition, it can be seen that the difference between the second winding 1112 shown in FIG. 11 and the second winding 112 shown in FIG. 1I is that the pins of the second winding 1112 shown in FIG. 11 are not comb-type pins, and the first pin 1130 and the second pin 1140 are respectively bar-type pin structures, but the effect achieved is similar to that of the embodiment shown in FIG. 1I. That is, by setting the first pin 1130 and the second pin 1140 connecting the second winding 1112 to the rectifier board on the circuit board in a surface mounting manner, the first pin 1130 and the second pin 1140 of the second winding 1112 are prevented from blocking the AC path as a whole, so that the gap between the switching elements can provide a path for the AC, that is, multiple second wires can be formed in the second direction of the circuit board, so that the harmonics can flow through multiple paths, thereby reducing the influence of the proximity effect between the wires, reducing the current loss on the rectifier board, and improving the overall power supply efficiency.

In some embodiments of the present disclosure, along the first direction X, the lengths of the first pin 1130 and the second pin 1140 are greater than the length of at least one switch element.

In some embodiments of the present disclosure, along the first direction X, the first pin 1130 and the second pin 1140 have the same length.

Of course, it is understandable that the solution in this embodiment can also be applied to the other aforementioned embodiments by analogy, which will not be elaborated here.

In some embodiments of the present disclosure, the first winding of the transformer is indirectly disposed on the magnetic core through a framework, that is, the first winding is disposed on the magnetic column through the framework, and the second winding is disposed on the outer side of the first winding. Similarly, the second winding can also be disposed on the outer side of the first winding through the framework.

In some embodiments of the present disclosure, the circuit board may be a multi-layer circuit board, and the switch element may be disposed on the topmost and/or bottommost circuit board.

In some embodiments of the present disclosure, the respective switch elements in the switch element group are connected by the first wire and the second wire according to a bridge rectifier circuit or a center-tapped rectifier circuit to form a rectifier circuit. In the embodiment, the bridge rectifier circuit and the center-tapped rectifier circuit are rectifier circuits well known to those skilled in the art, and their specific circuit structures are not described in detail here. Those skilled in the art use other rectifier circuit structures well known in the art to perform circuit connection of the switch element group, which should also be within the scope of protection of the present disclosure.

In some embodiments of the present disclosure, the second winding is a metal sheet or a PCB winding. The PCB winding can be a flexible PCB winding or a rigid PCB winding. For example, in the embodiment shown in FIG. 1B, the second winding 112 can also be a flexible PCB winding, and in the embodiment shown in FIG. 1C, the second winding 112 can also be a rigid PCB winding.

In some embodiments of the present disclosure, along the first direction X, at least one row of the switch elements (such as the first switch elements 1221A shown in FIG. 1D) is directly electrically connected to the comb-type pins. That is, the switch elements and the comb-type pins may be directly electrically connected without other components such as capacitors and resistors.

In some embodiments of the present disclosure, on the circuit board, multiple switch element groups can be electrically connected in series or in parallel, wherein the switch element groups are also electrically connected through the aforementioned first wire and second wire.

In some embodiments of the present disclosure, an output terminal is also provided on the circuit board. The rectifier board is connected to the output terminal through a copper busbar, thereby being electrically connected to an external device. As a result, the AC power output by the transformer in the present disclosure is rectified by the switch element group and does not need to be transmitted to the external device through the system board. Through the design of the output terminal, the transmission path of the high-current output signal is shortened, and the energy loss of the output signal during the transmission process is effectively reduced.

In some embodiments of the present disclosure, the comb-type pins and the rectifier board can be welded by via holes or surface mounting.

In some embodiments of the present disclosure, along the second direction Y, at least a portion of the second wire Q is formed between the oppositely arranged comb gaps of the second winding, the second wire Q is arranged on the circuit board, and the second wire Q is used to provide a path for harmonics.

In some embodiments of the present disclosure, the second winding may be a metal sheet or a PCB winding. Specifically, the metal sheet includes an iron sheet, a copper sheet, an aluminum sheet, a nickel sheet, a tungsten sheet, a molybdenum sheet, a cobalt sheet, etc., and also includes metal sheets made of various metal alloys, including stainless steel sheets, nickel-based alloy sheets, copper alloy sheets, and aluminum alloy sheets, etc. The PCB winding may be a flexible PCB winding or a rigid PCB winding.

In some embodiments of the present disclosure, distributed air gaps are provided on the transformer. The distributed air gaps can be provided on the magnetic columns, for example, and the distributed air gaps can also be filled with air gap forming materials that are non-electrically conductive and non-magnetically conductive, or filled with air gap forming materials with low magnetic permeability.

In the rectifier module and transformer provided by the embodiments of the present disclosure, by designing the pins that connect the second winding to the rectifier board to be comb-type pins, the comb-type pins include a plurality of comb teeth and comb gaps arranged adjacent to the comb teeth. The comb teeth are arranged along a first direction. At the same time, in coordination with the circuit design of the switch element group of the rectifier board, the switch elements of the same switch element group are arranged along a second direction perpendicular to the direction of the comb teeth. Thus, there are gaps between the switch elements, and the gaps can provide a path for alternating current, that is, multiple second wires can be formed in the second direction of the circuit board, so that harmonics have multiple paths to flow, thereby reducing the influence of the proximity effect between the wires, reducing the current loss on the rectifier board, and improving the overall power supply efficiency.

In the application examples, the terms “install”, “connection”, “connect”, “fix” and the like should be understood in a broad sense. For example, “connect” can be a fixed connection, a detachable connection, or an integral connection; “connection” can be a direct connection or an indirect connection through an intermediate medium. For those of ordinary skill in this art, the specific meanings of the above terms in the application examples can be understood according to specific circumstances.

In the description of the application embodiments, it should be understood that the directions or positional relationships indicated by the terms “up”, “down”, “left”, “right”, etc. are based on the directions or positional relationships shown in the accompanying drawings, and are only for the convenience of describing the application embodiments and simplifying the description, rather than indicating or implying that the device or unit referred to must have a specific direction, or be constructed and operated in a specific orientation, and therefore, should not be understood as a limitation on the application embodiments.

In the description of this specification, the description of the terms “one embodiment”, “some embodiments”, “specific embodiments”, etc. means that the specific features, structures, materials or characteristics described in conjunction with the embodiment or example are included in at least one embodiment or example of the application embodiment. In this specification, the schematic representation of the above terms does not necessarily refer to the same embodiment or example. Moreover, the specific features, structures, materials or characteristics described can be combined in any one or more embodiments or examples in a suitable manner.

The above are only preferred embodiments of the application embodiments and are not intended to limit the application embodiments. For those skilled in the art, the application embodiments may have various modifications and changes. Any modification, equivalent replacement, improvement, etc. made within the spirit and principle of the application embodiments shall be included in the protection scope of the application embodiments.

Those skilled in the art will readily appreciate other embodiments of the present disclosure after considering the specification and practicing the disclosure disclosed herein. This application is intended to cover any variations, uses, or adaptations of the present disclosure that follow the general principles of the present disclosure and include common knowledge or customary techniques in the art that are not disclosed in the present disclosure. The specification and examples are intended to be exemplary only, and the true scope and spirit of the present disclosure are indicated by the following claims.

It should be understood that the present disclosure is not limited to the exact structures that have been described above and shown in the drawings, and that various modifications and changes may be made without departing from the scope thereof. The scope of the present disclosure is limited only by the appended claims.

What is claimed is:

1. A rectifier module, comprising a transformer and a rectifier board,
wherein the transformer comprises:
a magnetic core, comprising a magnetic column;
a first winding, arranged on the magnetic column; and
a second winding, arranged outside the first winding;
wherein, two opposite sides of the second winding are respectively provided with comb-type pins, the comb-type pins are arranged along a first direction, the comb-type pins comprise at least two comb teeth, and a comb gap is provided adjacent to the comb teeth; and
wherein the rectifier board comprises:
a circuit board; and
a plurality of switch element groups arranged along the first direction, configured for rectifying an output current of the second winding, the switch element group being disposed on the circuit board and each switch element group comprising at least one switch element;
wherein in a second direction, the comb teeth are adjacent to the switch element; and the first direction and the second direction are perpendicular to each other.

2. The rectifier module according to claim 1, wherein the magnetic column comprises a middle column and at least two side columns, the first winding is arranged on the middle column, the second winding is arranged on the side columns, and along a third direction, the comb-type pins are extend away from the middle column, wherein, the third direction is perpendicular to the first direction and the second direction.

3. The rectifier module according to claim 1, wherein the second winding is a coil group formed by a plurality of coils electrically connected to each other, each coil has two side pins arranged opposite to each other, and the two side pins of the coil group respectively constitute the comb-type pins.

4. The rectifier module according to claim 1, further comprising an output terminal, wherein the output terminal is electrically connected to the rectifier board through a conductive sheet.

5. The rectifier module according to claim 1, wherein, along the second direction, at least one switch element is comprised between the comb teeth of the comb-type pins on the two sides of the second winding.

6. The rectifier module according to claim 5, wherein the switch element group comprises a first switch element, a second switch element, a third switch element and a fourth switch element in sequence along the second direction, and the comb teeth of the comb-type pins on both sides of the second winding are respectively arranged between the first switch element and the second switch element and between the third switch element and the fourth switch element.

7. The rectifier module according to claim 1, wherein, along the second direction, the comb teeth of the comb-type pins on both sides of the second winding are arranged in a same gap, and the gap refers to a gap between different rows of the switch elements in a same switch element group or a gap between the switch element and an edge of the rectifier board.

8. The rectifier module according to claim 1, wherein the second winding comprises a first sub-winding and a second sub-winding; the first sub-winding is arranged outside the first winding; the second sub-winding is arranged outside the first sub-winding; the comb-type pins are respectively provided on opposite sides of the first sub-winding and the second sub-winding; along the first direction, the comb teeth of the first sub-winding and the comb teeth of the second sub-winding are interlaced.

9. The rectifier module according to claim 1, wherein the second winding is a metal sheet or a PCB winding, and the pins of the second winding on the opposite sides along the second direction are interlaced to form a first group of interlaced comb-type pins, wherein the comb teeth on a first side of the second winding pass through the comb gap on a second side of the second winding and is extend along a third direction, and the comb teeth on the second side of the second winding pass through the comb gap on the first side of the second winding and is extend along the third direction; a second group of interlaced comb-type pins along the first direction are formed between the opposite sides of the second winding; the comb teeth in the second group of interlaced comb-type pins and the comb teeth in the first group of interlaced comb-type pins are disposed correspondingly; and
wherein, the third direction is perpendicular to the first direction and the second direction.

10. The rectifier module according to claim 1, wherein the second winding comprises a first sub-winding and a second sub-winding; the first sub-winding and the second sub-winding are oppositely arranged on two sides of the first winding; the comb-type pins are respectively provided on opposite sides of the first sub-winding and the second sub-winding; the comb teeth of the first sub-winding and the comb teeth of the second sub-winding are respectively arranged correspondingly, wherein the rectifier board comprises a first circuit board and a second circuit board, the comb-type pins on one side of the first sub-winding and the second sub-winding are electrically connected to the first circuit board, and the comb-type pins on the other side of the first sub-winding and the second sub-winding are electrically connected to the second circuit board.

11. The rectifier module according to claim 10, wherein the second winding further comprises a third sub-winding and a fourth sub-winding; the third sub-winding and the fourth sub-winding are respectively oppositely arranged outside the first sub-winding and the second sub-winding; the third sub-winding and the fourth sub-winding are respectively provided with the comb-type pins on opposite sides of the third sub-winding and the fourth sub-winding; the comb teeth of the third sub-winding and the comb teeth of the fourth sub-winding are respectively arranged correspondingly, and along the first direction, the comb teeth of the first sub-winding and the third sub-winding are interlaced, and the comb teeth of the second sub-winding and the fourth sub-winding are interlaced.

12. The rectifier module according to claim 8, wherein the circuit board comprises a first surface and a second surface arranged opposite to each other, and the switch element group comprises a first switch element and a second switch element, wherein the first switch element is located on the first surface and the second switch element is located on the second surface; the first switch element and the second switch element do not overlap along the second direction and are arranged along the first direction; and along the second direction, the comb-type pins on both sides of the first sub-winding and the second sub-winding are respectively located on an outer side of the first switch element and the second switch element.

13. The rectifier module according to claim 8, wherein the circuit board comprises a first surface and a second surface arranged opposite to each other, and the switch element group comprises a first switch element and a second switch element, wherein the first switch element is located on the first surface and the second switch element is located on the second surface; the first switch element and the second switch element at least partially overlap along the second direction and are arranged along the first direction; and along the second direction, the comb-type pins on both sides of the first sub-winding and the second sub-winding are respectively located on an outer side of the first switch element and the second switch element.

14. The rectifier module according to claim 8, wherein the switch element group comprises a first switch element and a second switch element, wherein the first switch element and the second switch element are located on a same surface of the circuit board, and the first switch element and the second switch element are arranged along the first direction; and along the second direction, the comb-type pins on both sides of the first sub-winding and the second sub-winding are respectively located on an outer side of the first switch element and the second switch element.

15. The rectifier module according to claim 9, wherein the switch element group comprises a first switch element and a second switch element; the first switch element and the second switch element are arranged along the second direction; wherein, along the second direction, the first group of interlaced comb-type pins are respectively located on an outer side of the first switch element and the second switch element, and the second group of interlaced comb-type pins are respectively located between the first switch element and the second switch element.

16. The rectifier module according to claim 1, wherein the second winding comprises N pieces, the N second windings are sequentially arranged on the circumferential side of the first winding, and the comb-type pins are respectively provided on the opposite sides of each second winding; the circuit board comprises N pieces, wherein the comb teeth of two adjacent second windings among the N second windings are respectively arranged correspondingly and electrically connected to one of the N circuit boards.

17. The rectifier module according to claim 1, wherein the switch elements of a same switch element group are arranged along the second direction.

18. The rectifier module according to claim 1, wherein the second winding comprises N separate windings, each separate winding comprises the comb-type pins, the comb-type pins of the N separate windings have different directions, the rectifier board comprises N separate rectifier boards, and the comb-type pins of the N separate windings are respectively arranged on the N separate rectifier boards.

19. The rectifier module according to claim 1, wherein the second winding comprises a plurality of separate windings, each of the separate windings comprises at least two oppositely arranged comb teeth, and the comb teeth of the plurality of separate windings are spliced to form the comb-type pins.

20. The rectifier module according to claim 1, wherein, along the second direction of the circuit board, at least a portion of a second wire is formed between the comb gaps oppositely arranged in the second winding, the second wire is arranged on the circuit board, and the second wire is used to provide a flow path for harmonics.

21. The rectifier module according to claim 1, further comprising a main board, wherein at least a portion of the rectifier board is arranged below the transformer, and the main board and the rectifier board are integrally formed.

22. A rectifier module, comprising a transformer and a rectifier board,
wherein the transformer comprises:
a magnetic core, comprising a magnetic column;
a first winding, disposed on the magnetic column; and
a second winding, arranged outside the first winding;
wherein, the second winding comprises a first pin and a second pin which are arranged opposite to each other;
wherein the rectifier board comprises:
a circuit board; and
a plurality of switch element groups arranged along a first direction, used for rectifying an output current of the second winding, the switch element group being disposed on the circuit board and comprising at least one switch element;
wherein the first pin and the second pin are bar-type pins, and are arranged on the circuit board in a surface mounting manner, along a second direction, the first pin and the second pin are adjacent to the switch element; and the first direction and the second direction are perpendicular to each other.

23. A transformer comprising a magnetic core, a first winding and a second winding; the magnetic core comprises a magnetic column, the first winding is arranged on the magnetic column, and the second winding is arranged outside the first winding; wherein two opposite sides of the second winding are respectively provided with comb-type pins, the comb-type pins are arranged along a first direction, the comb-type pins comprise at least two comb teeth, and a comb gap is arranged adjacent to the comb teeth.

24. The transformer according to claim 23, wherein the second winding is a coil group formed by a plurality of coils electrically connected to each other, each coil has two side pins arranged opposite to each other, and the two side pins of the coil group respectively constitute the comb-type pins.

25. The transformer according to claim 23, wherein the second winding comprises a first sub-winding and a second sub-winding; the first sub-winding is arranged outside the first winding; the second sub-winding is arranged outside the first sub-winding; the comb-type pins are respectively provided on opposite sides of the first sub-winding and the second sub-winding; along the first direction, the comb teeth of the first sub-winding and the comb teeth of the second sub-winding are interlaced.

26. The transformer according to claim 24, wherein the second winding is a metal sheet or a PCB winding, and the pins of the second winding on the opposite sides along the second direction are interlaced to form a first group of interlaced comb-type pins, wherein the comb teeth on a first side of the second winding pass through the comb gap on a second side of the second winding and is extend along a third direction, and the comb teeth on the second side of the second winding pass through the comb gap on the first side of the second winding and is extend along the third direction; a second group of interlaced comb-type pins along the first direction are formed between the opposite sides of the second winding, the comb teeth in the second group of interlaced comb-type pins and the comb teeth in the first group of interlaced comb-type pins are disposed correspondingly; and
wherein, the third direction is perpendicular to the first direction and the second direction.

27. The transformer according to claim 23, wherein the second winding comprises a first sub-winding and a second sub-winding; the first sub-winding and the second sub-winding are oppositely arranged on two sides of the first winding; the comb-type pins are respectively provided on opposite sides of the first sub-winding and the second sub-winding; the comb teeth of the first sub-winding and the comb teeth of the second sub-winding are respectively arranged correspondingly.

28. The transformer according to claim 27, wherein the second winding further comprises a third sub-winding and a fourth sub-winding; the third sub-winding and the fourth sub-winding are respectively oppositely arranged outside the first sub-winding and the second sub-winding; the third sub-winding and the fourth sub-winding are respectively provided with the comb-type pins on opposite sides of the third sub-winding and the fourth sub-winding; and along the first direction, the comb teeth of the first sub-winding and the third sub-winding are interlaced, and the comb teeth of the second sub-winding and the fourth sub-winding are interlaced.

29. The transformer according to claim 23, wherein the second winding comprises a plurality of separate windings, each of the separate windings comprises at least two oppositely arranged comb teeth, and the comb teeth of the plurality of separate windings are spliced to form the comb-type pins.
